(19) United States
(12) Patent Application Publication
(10) Pub. No.: US 2023/0420302 A1
(43) Pub. Date: Dec. 28, 2023

(54) METHODS FOR PREVENTING EPI DAMAGE DURING ISOLATION PROCESSES

(71) Applicant: Taiwan Semicondutor Manufacturing Company, Ltd., Hsinchu (TW)

(72) Inventors: Tzu-Ging Lin, Kaohsiung (TW); Shun-Hui Yang, Jungli (TW)

(21) Appl. No.: 17/846,493

(22) Filed: Jun. 22, 2022

(51) Int. Cl. H01L 21/8234; H01L 21/8238; H01L 27/092; H01L 29/66; H01L 29/78

(52) U.S. Cl. CPC H01L 21/823481; H01L 21/823431; H01L 21/823814; H01L 27/0924; H01L 29/66545; H01L 29/66818; H01L 29/7856

(57) ABSTRACT

A semiconductor device includes a first channel region extending in a first lateral direction, and comprising a first epitaxial structure; a dielectric structure extending in a second lateral direction and disposed next to the first epitaxial structure; a plurality of first semiconductor sections interposed between a first sidewall of the dielectric structure and the first epitaxial structure; and a plurality of first dielectric sections interposed between the first sidewall of the dielectric structure and the first epitaxial structure. The first dielectric sections are alternately arranged with the first semiconductor sections. The dielectric structure has a second sidewall opposite to the first sidewall in the first lateral direction. A maximum variance percentage of a distance between the first sidewall and second sidewall is less than about 50%.

### BACKGROUND

The semiconductor industry has experienced rapid growth due to continuous improvements in the integration density of a variety of electronic components (e.g., transistors, diodes, resistors, capacitors, etc.). For the most part, this improvement in integration density has come from repeated reductions in minimum feature size, which allows more components to be integrated into a given area.

### BRIEF DESCRIPTION OF THE DRAWINGS

FIG. 1 illustrates a flowchart of an example method for making transistor devices using a front end of line (FEOL) fabrication process in connection with the CPODE processes described herein, in accordance with some embodiments.

FIGS. 2, 3, 4, 5, 6, 7, 8, 9, 10, 11, 12, 13, 14, 15, 16, 17, 18, 19, 20, 21, 22, 23, 24, 25, and 26 illustrate various cross-sectional and perspective views of an example transistor device during various FEOL fabrication stages, made by the method of FIG. 2, in accordance with some embodiments;

FIGS. 27A and 27B include before and after cross-sectional, respectively, photographs of transistor devices that are subjected to an etching process that damages the transistor devices;

FIGS. 28 and 29 show cross-sectional photographs of transistor devices that are manufactured using the CPODE techniques described herein, which do not result in damage to the devices, in accordance with some embodiments;

FIG. 30 shows an example cross-sectional photograph of transistor devices made using the FEOL fabrication method of FIG. 1 with an overlay showing various etching stages used to carry out the CPODE techniques that do not result in transistor damage, in accordance with some embodiments;

FIGS. 31A and 31B illustrate cross-sectional photographs comparing etching techniques that damage transistor devices and the present CPODE techniques, which do not damage transistor devices, in accordance with some embodiments;

FIGS. 32 and 33 illustrate cross-sectional and perspective views of the example transistor device during the FEOL fabrication stages following a CPODE process, continuing the method of FIG. 2, in accordance with some embodiments;

FIG. 34 illustrates a flowchart of an example method for making transistor devices using a middle end of line (MEOL) fabrication process in connection with the CPODE techniques described herein, in accordance with some embodiments;

FIGS. 35, 36, 37, 38, 39, 40, 41, 42, 43, 44, 45, 46, 47, 48, and 49 illustrate various cross-sectional and perspective views of an example transistor device during various MEOL fabrication stages, made by the method of FIG. 34, in accordance with some embodiments; and

FIG. 50 shows an example cross-sectional photograph of transistor devices made using the MEOL fabrication method of FIG. 34 with an overlay showing various etching stages used to carry out the CPODE techniques that do not result in transistor damage, in accordance with some embodiments.

FIG. 51 shows an example diagram of a top view of a result of a CPODE process that is used to isolate one or more transistor devices, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over, or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” “top,” “bottom” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

The present disclosure provides various embodiments of semiconductor device manufacturing techniques that include a number of transistors. During or after the manufacture of the transistor devices, certain transistor devices can be isolated from one another by forming “cuts” in the substrate in which the transistors are formed. The cuts can be filled with a dielectric material to electrically isolate the transistors from one another. However, etching processes that do not implement the techniques described herein can result in damage to the transistors and logic structures manufactured using the fabrication techniques described herein. To address these issues, the present techniques implement a controlled and multi-stage etching process, which utilize different etching parameters when etching at different depths through the transistor devices. This etching process (sometimes referred to as cut polysilicon on diffusion edge (CPODE) technique) can be used to safely remove material from the material structures in which the transistor devices are formed without damaging the transistor devices.

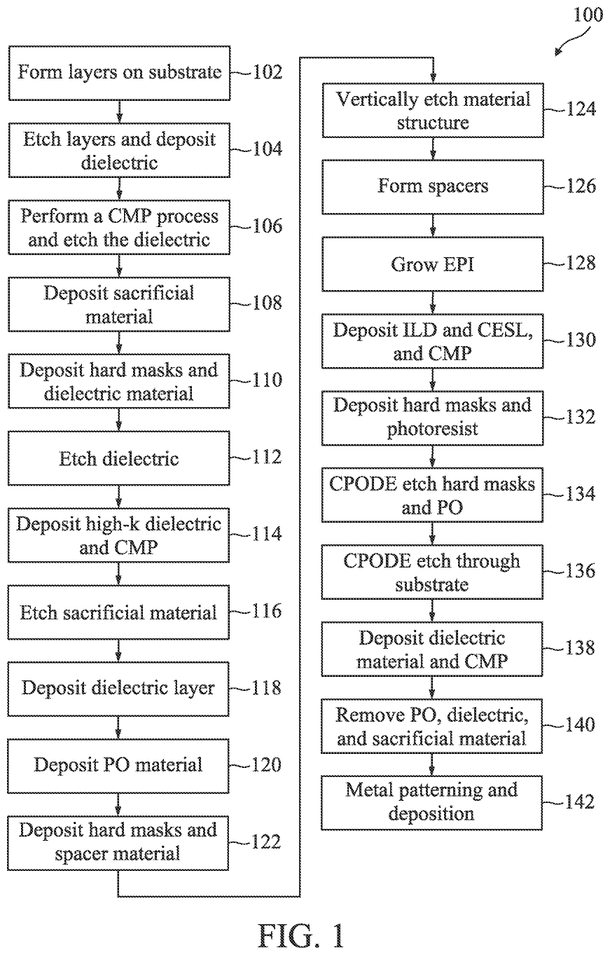

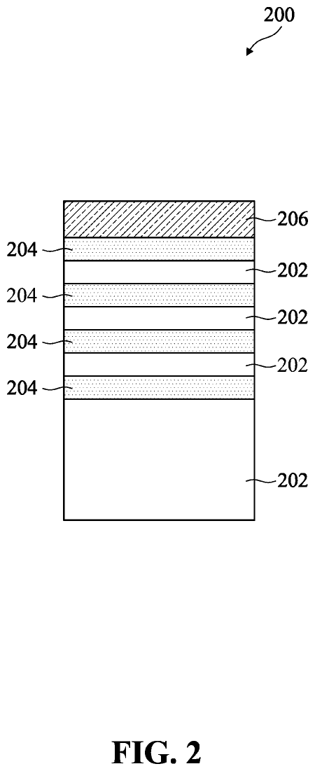

FIG. 1 illustrates a flowchart of an example method 100 for making transistor devices using a front end of line (FEOL) fabrication process in connection with the CPODE processes described herein, in accordance with some embodiments. For example, at least some of the operations (or steps) of the method 100 can be used to form transistor devices, such as a nanosheet transistor devices, nanowire transistor devices, vertical transistor devices, or the like, and to electrically isolate the transistor devices from one another according to a predetermined design using CPODE techniques. It is noted that the method 100 is merely an example, and is not intended to limit the present disclosure. Accordingly, it is understood that additional operations may be provided before, during, and after the method 100 of FIG. 1, and that some other operations may only be briefly described herein. Additionally, operations of the method 100 may be performed in an order different from that described herein to achieve desired results. In some embodiments, operations of the method 100 may be associated with the various perspective and cross-sectional views of the transistor devices at various fabrication stages as shown in FIGS. 2, 3, 4, 5, 6, 7, 8, 9, 10, 11, 12, 13, 14, 15, 16, 17, 18, 19, 20, 21, 22, 23, 24, 25, 26, 32, and 33 respectively, which will be discussed in further detail below.

In brief overview, the method 100 starts with operation 102 of forming layers on a substrate. The method 100 continues to operation 104 of etching layers and depositing dielectrics. The method 100 continues to operation 106 of performing a chemical mechanical polish (CMP) procedure and etching the dielectric. The method 100 continues to operation 108 of depositing sacrificial material. The method 100 continues to operation 110 of depositing hardmasks and dielectric material. The method 100 continues to operation 112 of etching the dielectric. The method 100 continues to operation 114 of depositing high-k dielectric and performing a CMP process. The method 100 continues to operation 116 of etching the sacrificial material. The method 100 continues to operation 118 of depositing a dielectric layer. The method 100 continues to operation 120 of depositing a polysilicon (PO) material. The method 100 continues to operation 122 of depositing hardmasks and spacer material. The method 100 continues to operation 124 of vertically etching the material structure. The method 100 continues to operation 126 of forming spacers. The method 100 continues to operation 128 of epitaxially growing semiconductor material. The method 100 continues to operation 130 of forming an interlayer dielectric (ILD), a contact etch stop layer (CESL), and performing a CMP process. The method 100 continues to operation 132 of depositing hardmasks and photoresist. The method 100 continues to operation 134 of CPODE etching hardmasks and PO. The method 100 continues to operation 136 of CPODE etching through substrate. The method 100 continues to operation 138 of depositing a dielectric and performing a CMP process. The method 100 continues to operation 140 of removing PO, dielectric, and sacrificial material. The method 100 continues to operation 142 of metal patterning and deposition.

As mentioned above, FIGS. 2-26, 32, and 33 illustrate, in various cross-sectional and perspective views, a portion of three-dimensional transistor devices at various fabrication stages of the method 100 of FIG. 1. It should be understood that the process steps shown in FIGS. 2-26, 32, and 33 may include a number of other devices such as inductors, fuses, capacitors, coils, etc., which are not shown in FIGS. 2-26, 32, and 33, for purposes of clarity of illustration.

Corresponding to operation 102 of FIG. 1, FIG. 2 is a cross-sectional view of a stack of layers that used to manufacture semiconductor devices using the techniques described herein. The stack of layers can be formed on a semiconductor substrate 202, and can include a number of alternating layers of the substrate material 202 and a first sacrificial material 204. A hardmask material can be deposited on the top layer of the sacrificial material 204.

The substrate 202 may be a semiconductor substrate, such as a bulk semiconductor, a semiconductor-on-insulator (SOI) substrate, or the like, which may be doped (e.g., with a p-type or an n-type dopant) or undoped. The substrate 202 may be a wafer, such as a silicon wafer. Generally, an SOI substrate includes a layer of a semiconductor material formed on an insulator layer (not shown). The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 202 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The one or more layers of the sacrificial material 204 may be formed on the substrate material 202 using a material deposition process or an epitaxial growth process. The sacrificial material 204 can be removed in later process steps, and can be formed from a material that has different material properties than the substrate material 202, to facilitate selective removal or deposition techniques described herein. The sacrificial material 204 can be an alloy semiconductor material, such as SiGe.

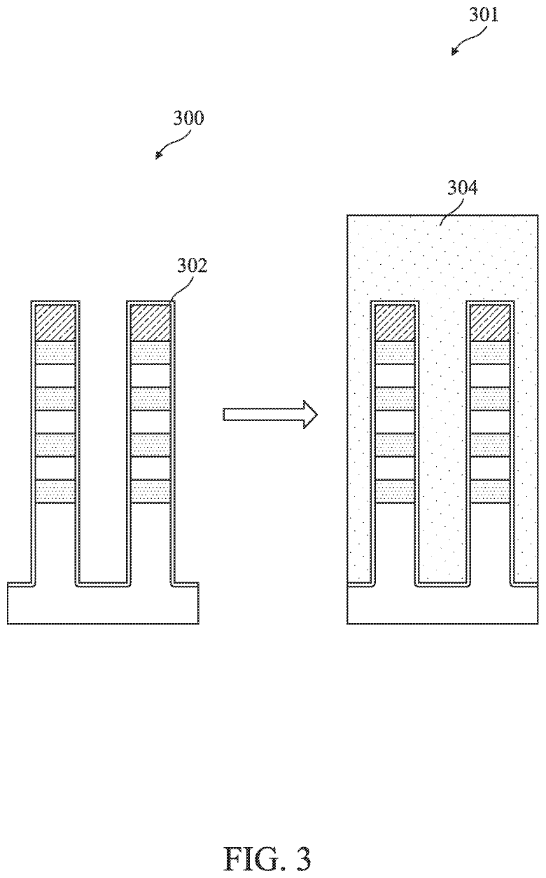

Corresponding to operation 104 of FIG. 1, FIG. 3 are cross-sectional views 300 and 301 of the stack of layers of FIG. 2, after an etching process has been applied to structures. As shown, the views 300 and 301 show the deposition of two layers of a first dielectric material 302 and a second dielectric material 304. Although two etched structures are shown, it should be appreciated that the device can include any number of etched structures which can be subsequently using an appropriate patterning and etching technique, such as while remaining within the scope of the present disclosure.

The first dielectric material 302 and the second dielectric material 304 can be any type of insulating material, including various oxides, such as silicon oxide, a nitride, or other insulators, or combinations thereof. The layer of the first dielectric material can be formed using any suitable material deposition technique, including atomic layer deposition (ALD), a high density plasma chemical vapor deposition (HDP-CVD), a flowable CVD (FCVD) (e.g., a CVD-based material deposition in a remote plasma system and post curing to make it convert to another material, such as an oxide), the like, or combinations thereof. Other dielectric materials and other formation processes may be used. In an example, the first dielectric material 302 or the second dielectric material 304 can be a silicon oxide. Similarly, the second dielectric material may be a different type of insulation material than the first dielectric material, and can be deposited using a suitable material deposition technique.

The first dielectric material 302 can be formed as a liner, and the second dielectric material can be deposited on top of the liner to encase the etched structures shown in the cross-sectional view 300. The first dielectric material 302 can be a liner oxide. The liner oxide (e.g., silicon oxide) may be a thermal oxide formed through a thermal oxidation of a surface layer of the substrate 202, although other suitable method may also be used to form the liner oxide.

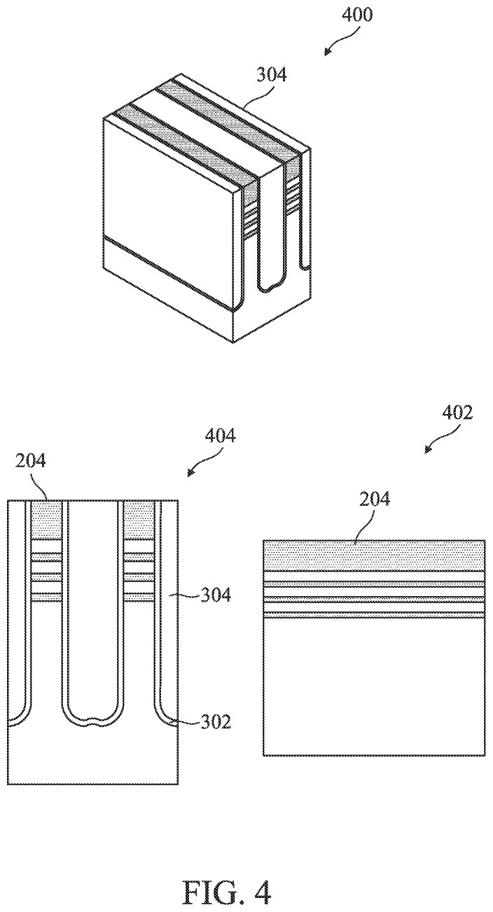

Corresponding to operation 106 of FIG. 1, FIG. 4 shows a perspective view 400 and cross-sectional views 402 and 404 of the stack of layers following a CMP process and an etching process. As shown, the etching process has removed the hardmask shown in FIGS. 2-3, and the CMP and etching process has made the top-most layer of the sacrificial material 204 level with the second dielectric material 304 described in connection with FIG. 3. The cross-sectional view 404 shows the first dielectric material 302 is also exposed at the top of the device following the CMP process. Any type of suitable CMP process or etching process can be used to remove the top layers of the hardmask 206, the first dielectric material 302, and the second dielectric material 304, including dry or wet etching techniques. The etching techniques may be implemented using the sacrificial material 204 as an etch-stop layer.

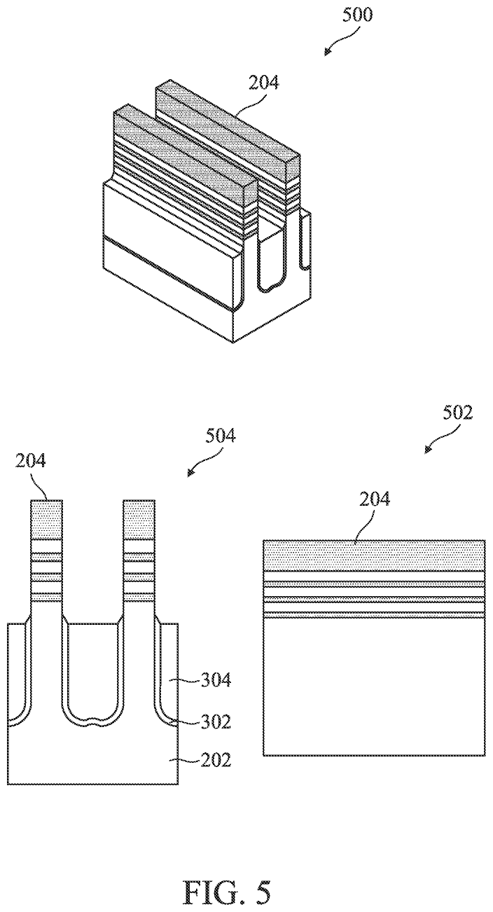

Still corresponding to operation 106 of FIG. 1, FIG. 5 shows a perspective view 500 and cross-sectional views 502 and 504 of the stack of layers following an etching process to remove portions of the first dielectric material 302 and the second dielectric material 304. As shown, the selective etching process is selective to the first dielectric material 302 and the second dielectric material 304, and does not remove the sacrificial material 204 or the substrate material 202. The etching process can be performed until the lower-most layer of the sacrificial material 204 is exposed, along with a small portion of the substrate material 202 below the lower-most layer of the sacrificial material 204. Any type of suitable etchant or material removal process may be used that is selective to the second dielectric material 304 and/or the first dielectric material 302. In some embodiments, two etching steps may be performed, one that is selective to the second dielectric material 304, and a second that is selective to the first dielectric material 302.

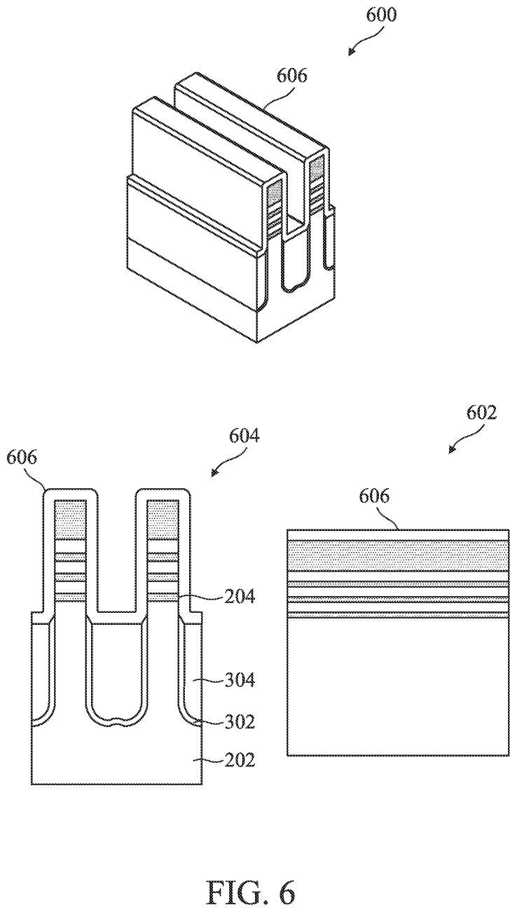

Corresponding to operation 108 of FIG. 1, FIG. 6 shows a perspective view 600 and cross-sectional views 602 and 604 of the stack of layers following deposition of a second sacrificial material 606. The second sacrificial material 606 may be any type of suitable that may be deposited or epitaxially grown on the substrate material 202 or the sacrificial material 204. In some embodiments, the second sacrificial material 606 may be the same material as the sacrificial material 204, or may be a different material. The second sacrificial material 606 can be a semiconductor alloy material, such as SiGe or another suitable sacrificial material. The second sacrificial material 606 can be formed to encapsulate the top of the device, as shown in the perspective view 600 and the cross-sectional view 604. The sacrificial material 606 may be formed as a cladding layer over the device.

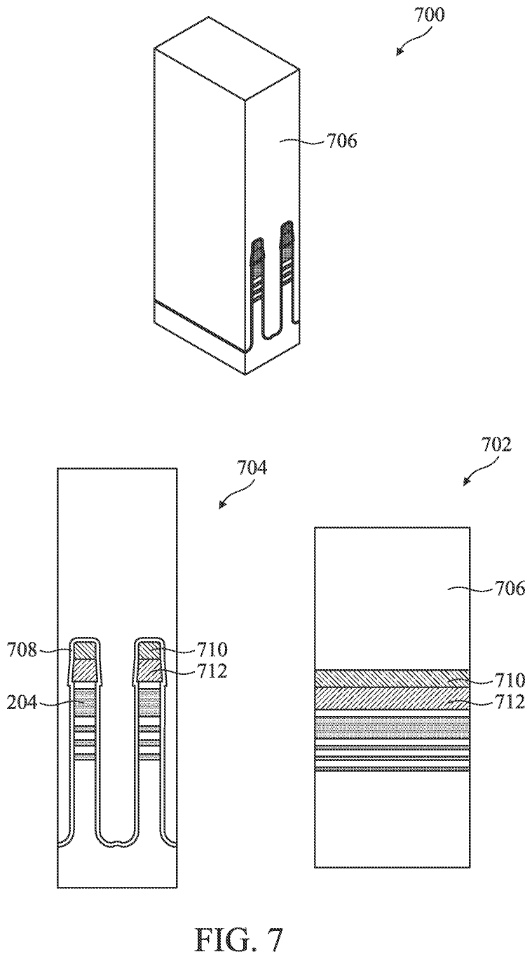

Corresponding to operation 110 of FIG. 1, FIG. 7 shows a perspective view 700 and cross-sectional views 702 and 704 of the stack of layers following formation of a first hardmask 712, a second hardmask 710, a liner material 708, and a third dielectric material 706. The liner material 708 can first be formed to cover the second sacrificial material 606, which is formed as a cladding layer. The liner material 708 can be deposited as a thin interface between the second sacrificial material 606 and the third dielectric material 706. The liner material 708 can be formed using any suitable material deposition process, and may include materials such as SiCN. After depositing the liner material 708, a first hardmask 712 can be formed on liner material 708 over the top layer of the sacrificial material 204. The first hardmask 712 can be any suitable hardmask material, such as SiN, and can be patterned and formed using any suitable material deposition technique. The second hardmask 710 can be patterned or selectively deposited on top of the first hardmask 712. The second hardmask 710 may be a different material than the first hardmask 712, such as an oxide material (e.g., SiOₓ). After forming the first hardmask 712 and the second hardmask 710, an additional layer of the liner material 708 can be formed using similar techniques to those described above. Next, a third dielectric material 706 can be formed on top of the liner material 708. The third dielectric material 706 can be formed using techniques similar to those used to form the second dielectric material 304 described in connection with FIG. 3. In some embodiments, the third dielectric material 706 can be the same material as the second dielectric material 304.

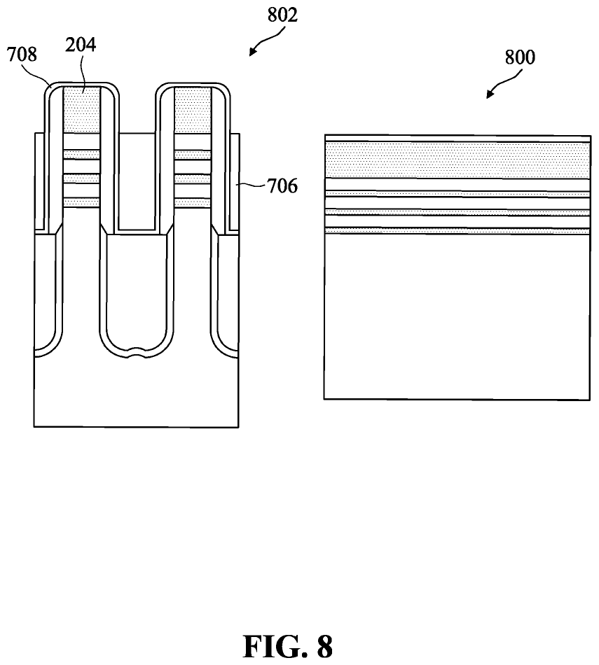

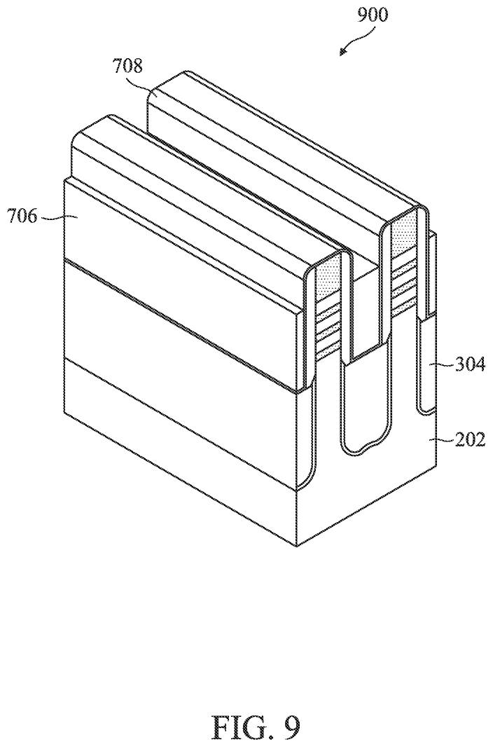

Corresponding to operation 112 of FIG. 1, FIG. 8 shows a cross-sectional views 800 and 808 of the stack of layers following an etching process that removes the first hardmask 712, the second hardmask 710, and the third dielectric material 706. FIG. 9 shows a perspective view 900 of the stack of layers following the same etching process. As shown in the cross-sectional view 800, the first hardmask 712 and the second hardmask 710 have been removed, along with the upper portion of the third dielectric material 706. This exposes an upper portion of the liner material 708. Any suitable etching processes, including dry or wet etching processes, can be used to remove the aforementioned materials. As shown in the cross-sectional view 802, the third dielectric material 706 can be etched until it is above level with the bottom of the top layer of the sacrificial material 204.

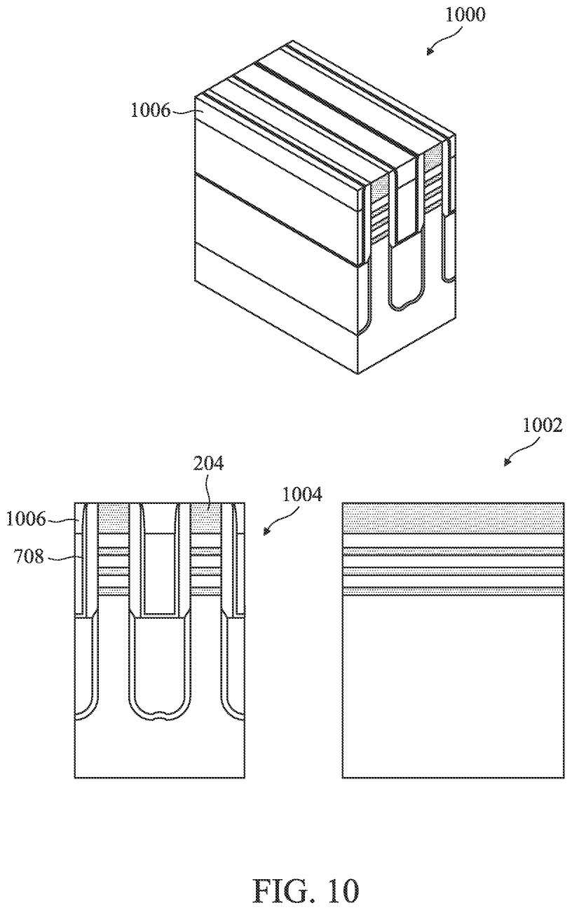

Corresponding to operation 114 of FIG. 1, FIG. 10 shows a perspective view 1000 and cross-sectional views 1002 and 1004 of the stack of layers following formation of a high-k dielectric material 1006. The high-k dielectric material 1006 can be an insulating material with a relative large dielectric constant, k. The high-k dielectric material 1006 may include oxide materials or other insulating materials. The high-k dielectric material 1006 can be formed using any suitable material deposition technique, such as chemical vapor deposition (CVD), physical vapor deposition (PVD), ALD, or other suitable processes. After forming the high-k dielectric material 1006, a CMP process can be performed to planarize the device. This can also remove an upper portion of the liner material 708, and expose the upper layer of the sacrificial material 204. As shown, the sacrificial material 204 is level with the high-k dielectric material 1006 following the CMP process.

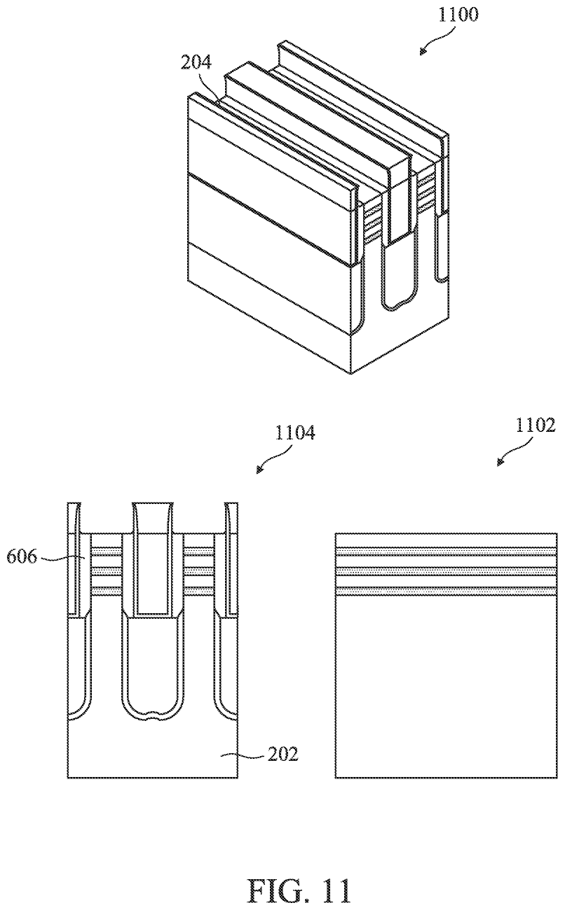

Corresponding to operation 116 of FIG. 1, FIG. 11 shows a perspective view 1100 and cross-sectional views 1102 and 1104 of the stack of layers following a selective etching process. As shown in the perspective view 1100 and the cross-sectional view 1104, the etching process can remove the top layer of the sacrificial material 204. The perspective view 1100 shows a very thin layer of the sacrificial material 204 remains on top of the substrate material 202. Additionally, the etching process can remove an upper portion of the second sacrificial material 606. The etching process used may be selective to both the sacrificial material 204 and the second sacrificial material 606. In some embodiments, multiple selective etching processes may be used to remove the upper portions of the sacrificial material 204 and the second sacrificial material 606. As shown, the second sacrificial material 606 can be etched until level with the top layer of the substrate material 202.

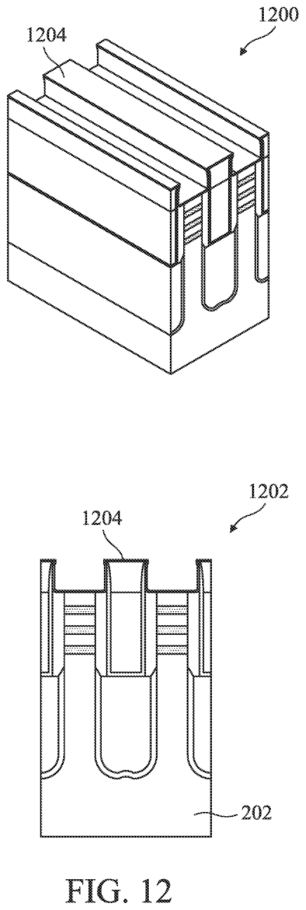

Corresponding to operation 118 of FIG. 1, FIG. 12 shows a perspective view 1200 and a cross-sectional views 1202 of the stack of layers following the deposition of a fourth dielectric material 1204. The fourth dielectric material 1204 can be formed as a thin layer over the top of the device. The fourth dielectric material 1204 can be any type of suitable insulating material, such as an oxide material. The fourth dielectric material 1204 can be formed using any type of suitable material deposition technique, such as CVD, PVD, ALD, or other suitable processes. The fourth dielectric material 1204 can electrically isolate the substrate material 202 from additional material layers added in future process steps. As shown in the perspective view 1200, the fourth dielectric material 1204 can cover the entirety of the top of the device.

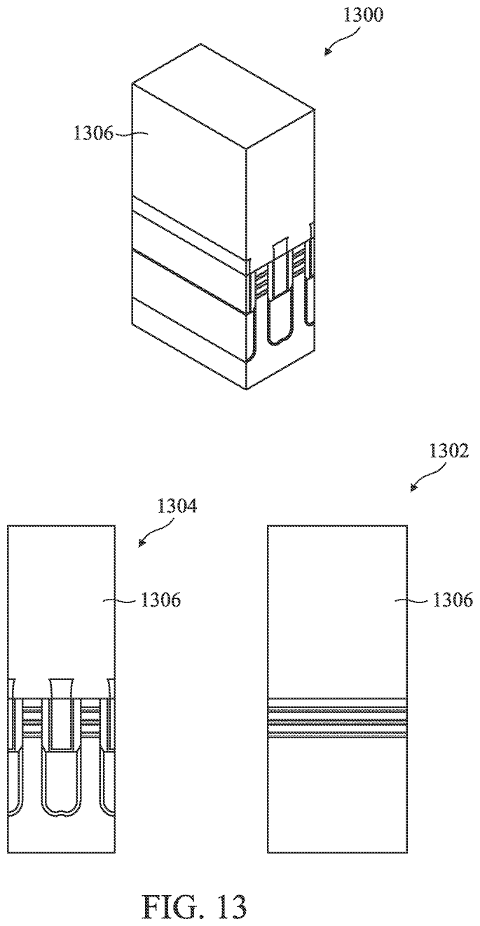

Corresponding to operation 120 of FIG. 1, FIG. 13 shows a perspective view 1300 and cross-sectional views 1302 and 1304 of the stack of layers following the deposition of a PO material 1306. As shown, the PO material 1306 covers the entirety of the device, and is deposited on the fourth dielectric material 1204 described in connection with FIG. 12. The PO material 1306 can be, for example, a polysilicon material. The PO material 1306 can be used as a placeholder region, which will be removed in layer process steps to form metal gate materials. The PO material 1306 can be deposited using any suitable material deposition technique, including ALD, CVD, PVD, among other techniques. PO material 1306 can be deposited to a predetermined thickness, according to design parameters of the device.

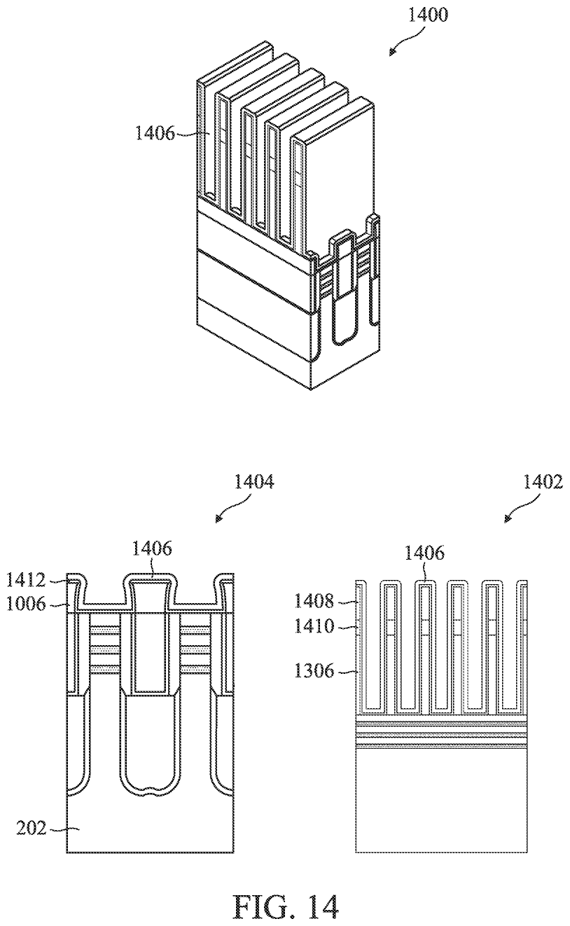

Corresponding to operation 122 of FIG. 1, FIG. 14 shows a perspective view 1300 and cross-sectional views 1302 and 1304 of the stack of layers following the patterning and etching the of the PO material 1306. To etch the PO material 1306, a third hardmask 1410 and a fourth hardmask 1408 can first be patterned on top of the PO material 1306. The third hardmask 1410 and the fourth hardmask 1408 can be patterned, for example, using a photo resist material, such that the third hardmask 1410 and the fourth hardmask 1408 form strips that are perpendicular to the fin structures formed from the sacrificial material 204 and the substrate material 202. The third hardmask 1410 and the fourth hardmask 1408 can be similar to the first hardmask 712 and the second hardmask 710 described in connection with FIG. 7, and can be made from similar materials and formed using similar techniques. After depositing the third hardmask 1410 and the fourth hardmask 1408, the PO material 1306 can be selectively and vertically etched, such that the PO material 1306 below the third hardmask 1410 and the fourth hardmask 1408 are not removed by the etching process. Any suitable vertical etching process or material removal process can be used.

After etching the PO material 1306, a layer of a second liner material 1412 can be deposited over the top of the device, covering the PO material 1306, the third hardmask 1410 and the fourth hardmask 1408, the substrate material 202, and the high-k dielectric material 1006. The second liner material 1412 can be similar to the liner material 708 described in connection with FIG. 7. The second liner material 1412 can be any type of suitable insulating material, such as an oxide or another type of insulator. After depositing the second liner material 1412, a layer of a spacer material 1406 is deposited over the device. As shown, the layer of the spacer material evenly covers all materials on the surface of the device. The spacer material 1406 can be deposited using any suitable material deposition technique, such as ALD, CVD, PVD, among others. The spacer material can be used to protect materials on the device from etching processes in further process steps.

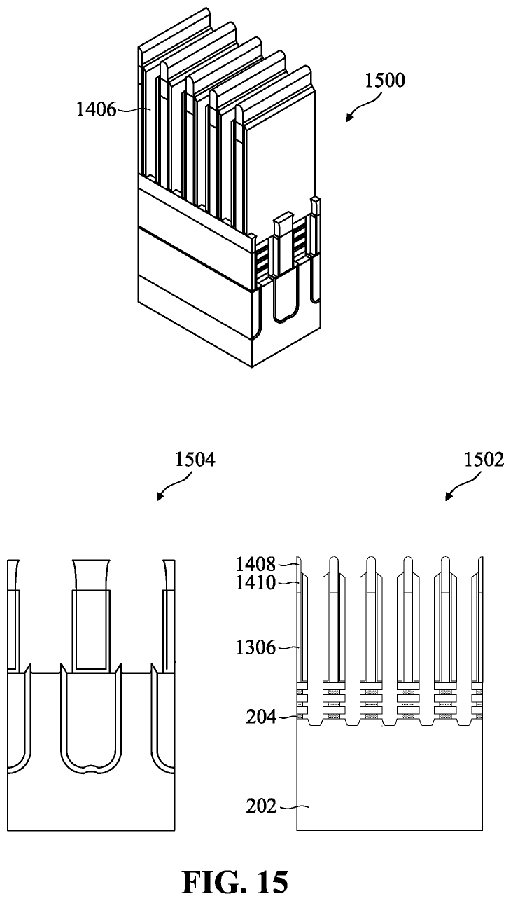

Corresponding to operation 124 of FIG. 1, FIG. 15 shows a perspective view 1500 and cross-sectional views 1502 and 1504 of the stack of layers following a vertical etching process. As shown, the materials added in the previous process step are vertically etched to create a number of troughs in the substrate material 202 between the PO material 1306 structures. The vertically etching process can be performed to etch the substrate to below the bottom-most layer of the sacrificial material 204. As shown in the cross-sectional view 1502, the troughs are formed through the alternating layers of the substrate material 202 and the sacrificial material 204. The etching process causes the layers of the sacrificial material 204 to be recessed relative to the sides of the troughs. The third hardmask 1410, the fourth hardmask 1408, and the spacer material 1406 protect the PO material 1306 from the etching process, such that it remains intact following the etching process and defines the walls of each trough. Although some of the layers of the sacrificial material 204 are etched, portions of the sacrificial material 204 remain under each PO material 1306 structure.

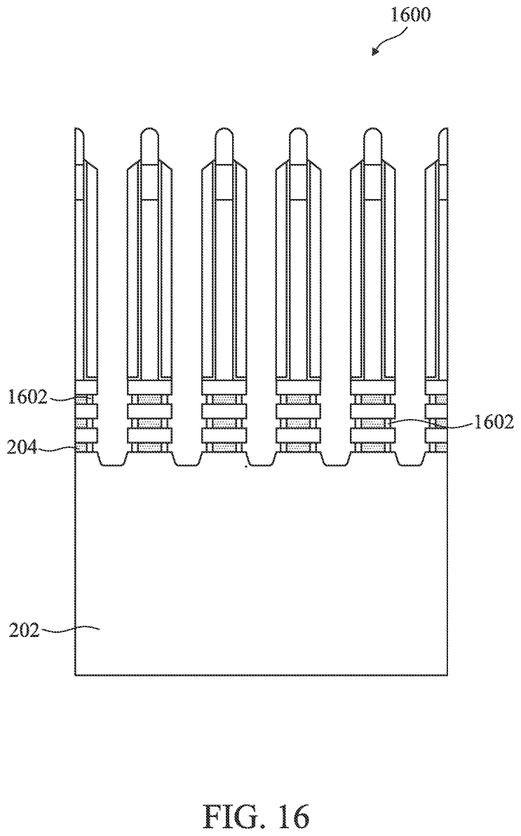

Corresponding to operation 126 of FIG. 1, FIG. 16 shows a cross-sectional view 1602 and 1304 of the stack of layers after forming spacers 1602 on the sacrificial material 204. As described above, the prior etching process caused the layers of the sacrificial material 204 making up portions of the walls of the troughs in the substrate material 202 to become recessed slightly. The spacers 1602 can be formed in air gaps between the layers of the substrate material 202, which were created when recessing the sacrificial material 204. The spacers 1602 can be formed from any type of suitable insulating material with a relatively low dielectric constant k, such as silicon oxide, silicon oxycarbonitride (SiOCN), or the like. Any suitable deposition method, such as thermal oxidation, CVD, or the like, may be used to form the spacers 1602. The shapes and formation methods of the spacers 1602 as illustrated in FIG. 16 are merely non-limiting examples, and other shapes and formation methods are possible. These and other variations are fully intended to be included within the scope of the present disclosure.

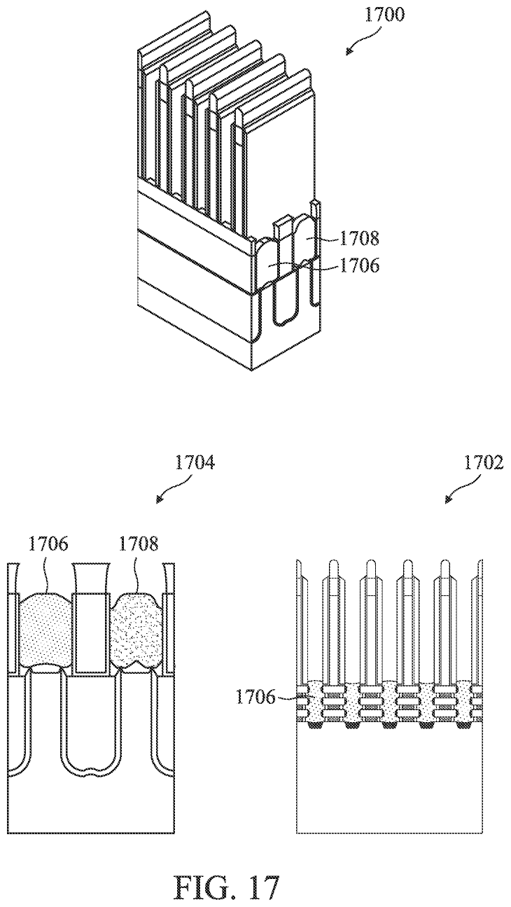

Corresponding to operation 128 of FIG. 1, FIG. 17 shows a perspective view 1700 and cross-sectional views 1702 and 1704 of the stack of layers following epitaxial growth of a first doped semiconductor material 1706 and a second doped semiconductor material 1708. Each of the first doped semiconductor material 1706 and the second doped semiconductor material 1708 can be epitaxially grown using the substrate 202 as a seed material in the troughs formed in previous etching steps. To form each of first doped semiconductor material 1706 and the second doped semiconductor material 1708, selective patterning may be performed to guide the epitaxial growth of the first doped semiconductor material 1706 and the second doped semiconductor material 1708 in respective regions of each trough. For example, a dielectric material (not shown) or other masking material may be used to prevent epitaxial growth on some regions of the substrate material 202, allowing for selective growth of both P-type and N-type semiconductive material.

The first doped semiconductor material 1706 and the second doped semiconductor material 1708 may be doped to have the same or a different polarity. The first doped semiconductor material 1706 and the second doped semiconductor material 1708 may have an impurity (e.g., dopant) concentration in a range from about 1×10¹⁹ cm⁻³ to about 1×10²¹ cm⁻³. P-type impurities, such as boron or indium, or N-type impurities, such as phosphorous or arsenide, may be implanted in the first doped semiconductor material 1706 or the second doped semiconductor material 1708. In some embodiments, the first doped semiconductor material 1706 and the second doped semiconductor material 1708 may be in situ doped during their growth.

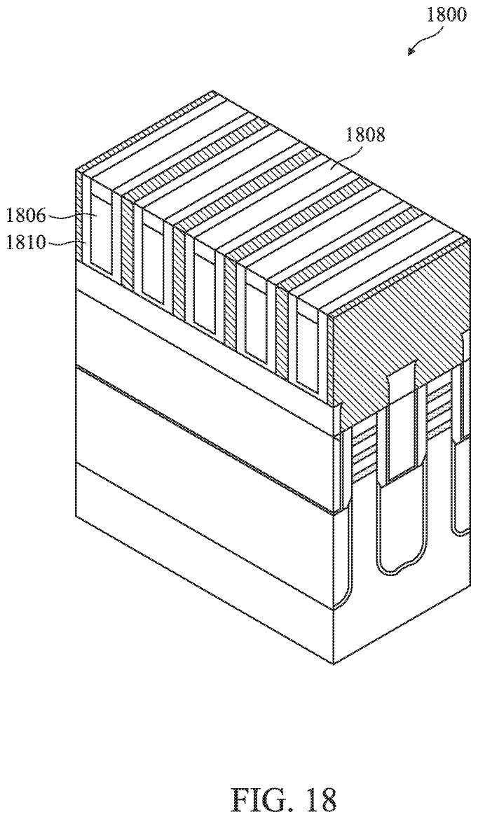

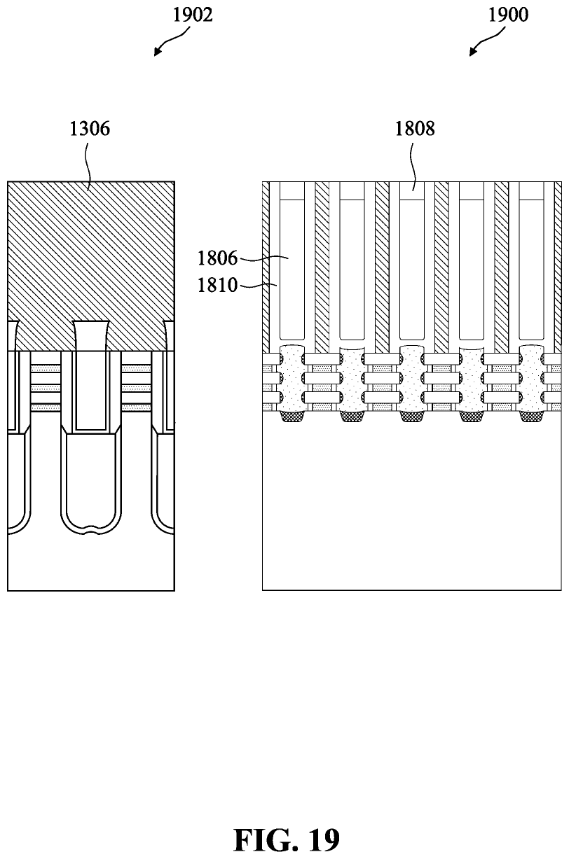

Corresponding to operation 130 of FIG. 1, FIGS. 18 and 19 show a perspective view 1800 and cross-sectional views 1900 and 1902 of the stack of layers following the deposition of a CESL material 1810, an ILD material 1806, and a dielectric layer 1808. First, a CESL material 1202 is formed over the first doped semiconductor material 1706 and the second doped semiconductor material 1708. The CESL material 1810 can function as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like.

Next, the ILD material 1806 is formed over the CESL material 1810. In some embodiments, the ILD material 1806 is formed of a dielectric material such as silicon oxide, phosphosilicate glass (PSG), borosilicate glass (BSG), boron-doped phosphosilicate Glass (BPSG), undoped silicate glass (USG), or the like, and may be deposited by any suitable method, such as CVD, PECVD, or FCVD. After the ILD material 1806 is formed, an optional dielectric layer 1808 is formed over the ILD material 1806. The dielectric layer 1808 can function as a protection layer to prevent or reduces the loss of the ILD material 1806 in subsequent etching processes. The dielectric layer 1808 may be formed of a suitable material, such as silicon nitride, silicon carbonitride, or the like, using a suitable method such as CVD, PECVD, or FCVD. After the dielectric layer 1808 is formed, a planarization process, such as a CMP process, may be performed to achieve a level upper surface for the dielectric layer. The CMP may also remove the third hardmask 1410 and the fourth hardmask 1408 and portions of the CESL material 1810. After the planarization process, the upper surface of the dielectric layer 1808 is level with the upper surface of the PO material 1306, in some embodiments.

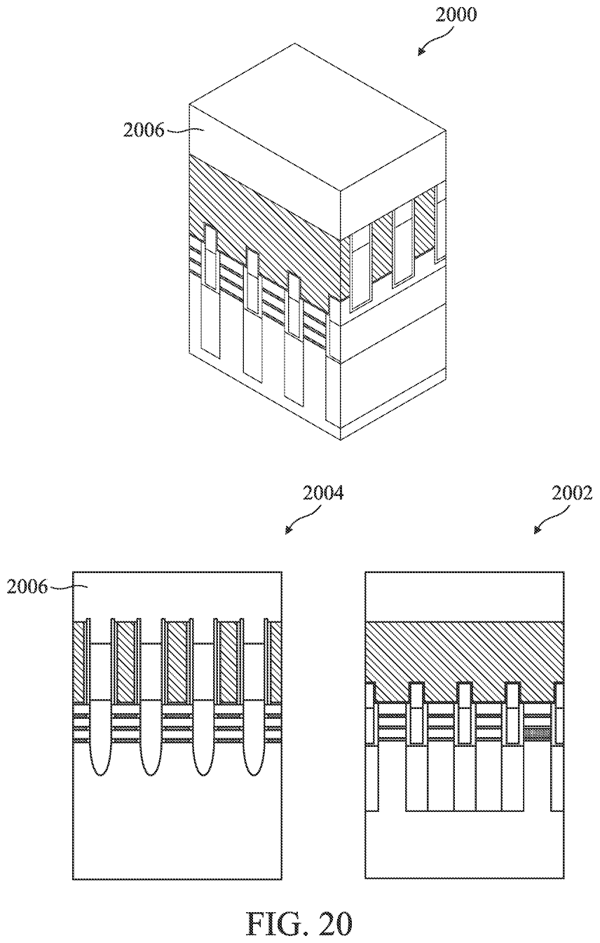

Corresponding to operation 132 of FIG. 1, FIG. 20 shows a perspective view 2000 and cross-sectional views 2002 and 2004 of the stack of layers at the start of a CPODE process. At the start of the CPODE process, a hardmask layer 2006 can be deposited over the surface of the device. The hardmask layer 2006 can be any type of suitable dielectric material, including as silicon nitride, silicon carbonitride, or the like, and may be formed using a suitable method such as CVD, PECVD, or FCVD. After the hardmask layer 2006 is formed, a planarization process, such as a CMP process, may be performed.

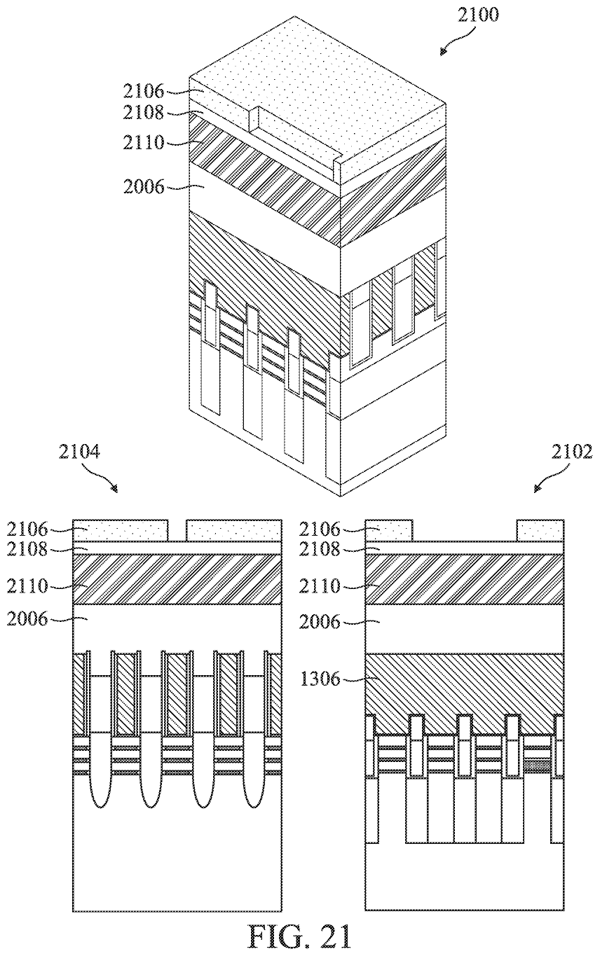

Still corresponding to operation 132 of FIG. 1, FIG. 21 shows a perspective view 2100 and cross-sectional views 2102 and 2104 of the stack of layers undergoing a CPODE process. As shown, a second hardmask layer 2110 and a third hardmask layer 2108 are formed on top of the hardmask layer 2006, followed by a layer of patterned photoresist 2106. As shown, the patterned photoresist includes a slot-shaped opening, which is positioned to guide further etching processes. To pattern the photoresist 2106, the photoresist 2106 is deposited, irradiated (exposed), and developed to remove predetermined portions of the photoresist 2106. The remaining photoresist 2106 protects the underlying layers from subsequent processing steps, such as etching.

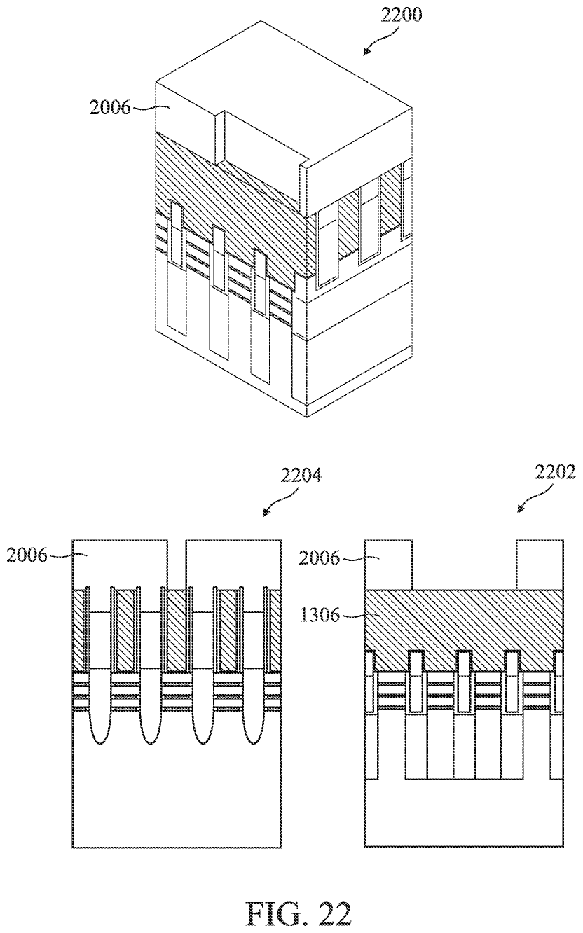

Corresponding to operation 134 of FIG. 1, FIG. 22 shows a perspective view 2200 and cross-sectional views 2202 and 2204 of the stack of layers undergoing the CPODE process to isolate one or more transistor structures that will be formed in the stack of layers. As shown, using suitable etching processes, each of the photoresist 2106, the second hardmask layer 2110, and the third hardmask layer 2108 have been removed, along with a slot-shaped portion of the hardmask 2006. As shown, the slot-shaped portion that is removed from the hardmask 2006 was previously defined by the corresponding opening in the photoresist 2106. The etching process can be a vertical etching process towards the PO material 1306, with the PO material 1306 serving as an etch stop layer.

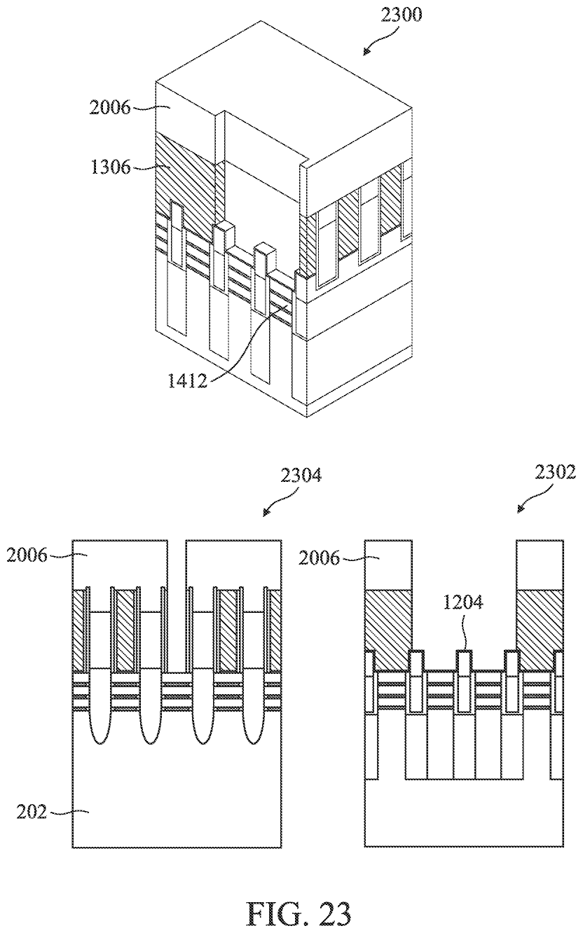

Still corresponding to operation 134 of FIG. 1, FIG. 23 shows a perspective view 2300 and cross-sectional views 2302 and 2304 of the stack of layers undergoing the CPODE process. As shown, an additional vertical etching process in the direction towards the substrate 202 is performed to remove a portion of the PO material 1306. Any suitable etching process, such as a dry etching process or a wet etching process, can be used to remove the PO material 1306. The fourth dielectric material 1204 can act as an etch-stop for the etching process. The etching process can be directional, such that the PO material 1306 is removed in the predetermined slot-shape defined by the hardmask layer 2006.

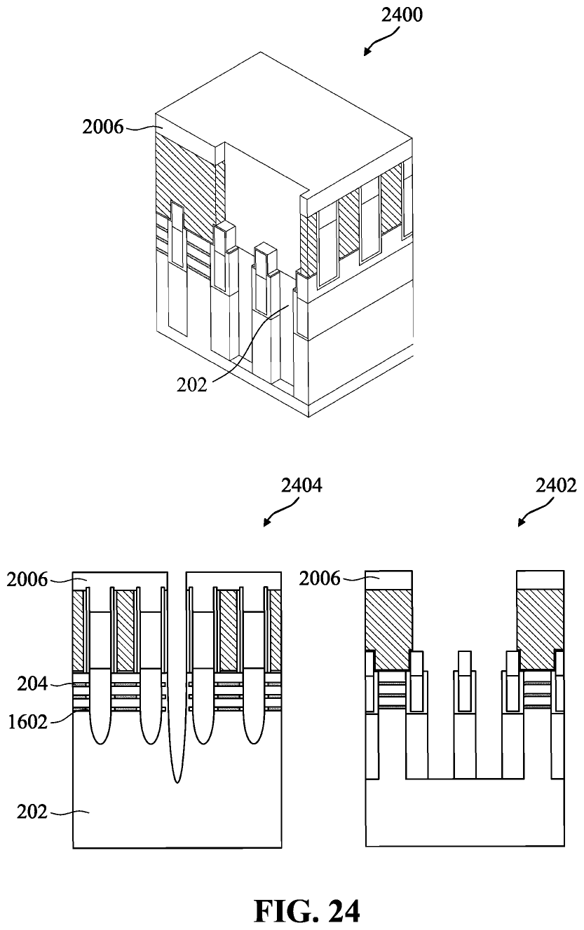

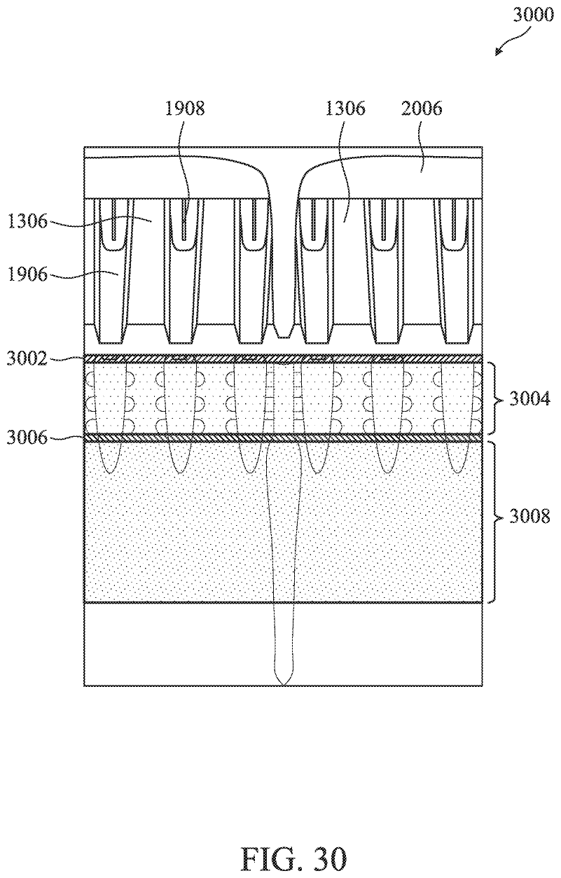

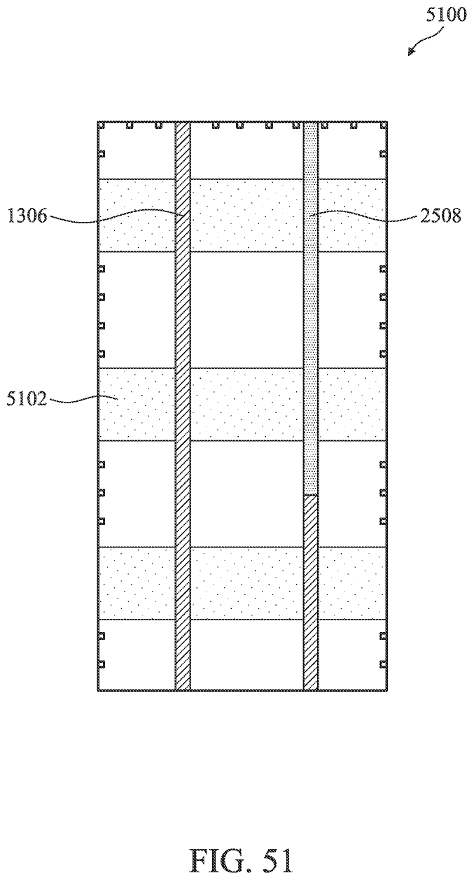

Corresponding to operation 136 of FIG. 1, FIG. 24 shows a perspective view 2400 and cross-sectional views 2402 and 2404 of the stack of layers undergoing the CPODE process. At this stage in the CPODE process, one or more directional etching processes are utilized to remove portions of the fourth dielectric material 1204, the substrate 202, and the layers of the sacrificial material 204 that are positioned beneath the slot defined by the hardmask layer 2006. To do so, particular etching processes can be utilized to prevent damage to the spacers 1602 during material removal. Implementations that do not utilize the techniques described herein may cause damage to the structures in the stack of layers during the etching process. The etched opening shown in FIG. 24 is a result of utilizing the techniques described in connection with FIG. 30. An example diagram of a top view of a result of a CPODE process is shown in FIG. 51.

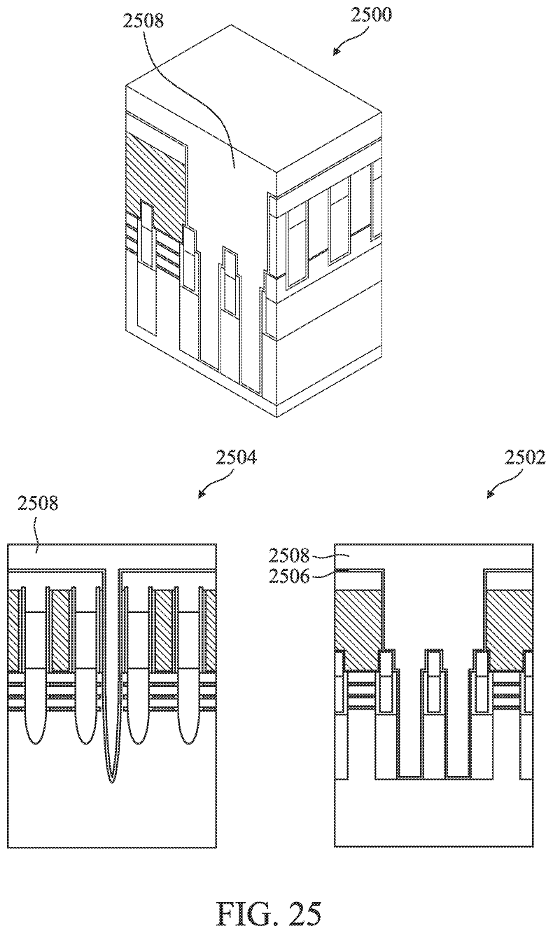

Referring to FIG. 51, shows an example diagram of a top view 5100 of a result of a CPODE process that is used to isolate one or more transistor devices, in accordance with some embodiments. As shown, in the view 5100, the CPODE process can be used to isolate individual transistor structures 5102 from one another by etching and replacing portions of the PO material 1306 and replacing with a dielectric filler material 2508 (described in greater detail in connection with FIG. 25). Using the present techniques, the etching process to isolate the transistor structures described herein does not damage any portions of the transistor structures, resulting in reduced leakage current.

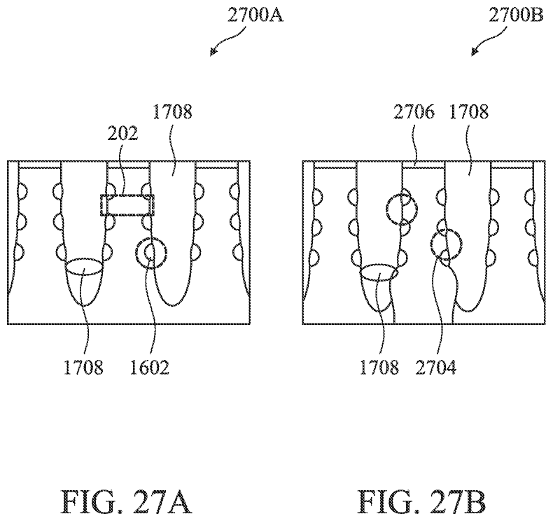

Referring back to operation 136 of FIG. 1, a before and after comparison of an etching process that does not utilize the particular etching techniques described herein are shown in FIGS. 27A and 27B, respectively. FIG. 27A shows a cross-sectional photograph 2700A of a stack of layers manufactured using the techniques described herein. As shown, prior to the etching process, the substrate material 202 positioned between the spacers 1602 is intact, and the doped semiconductor material 1708 is undamaged. However, as shown in the cross-sectional photograph 2700B of FIG. 27B, following an etching process that does not utilize the techniques described herein. As shown, following the etching process, a number of semiconductor sections 2706 (made from etched substrate material 202) are separated from one another by the spacers 1602. Although the semiconductor section 2706 has minor damage, the region 2704 shows that the semiconductor section 2706 has been completely removed, and includes damage to the doped semiconductor material 1708 due to over-etching. This can result in unintended short-circuits, current leakage, or logic circuits that do not function properly. Other damage, such as damage to the spacers 1602, is also possible when not utilizing the techniques described herein.

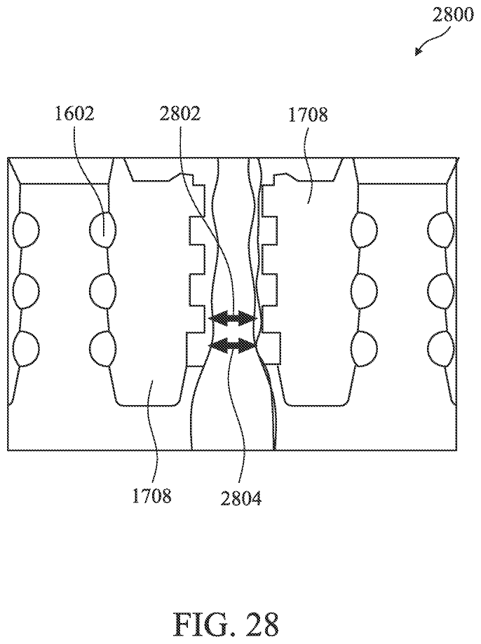

FIG. 28 shows a cross-sectional photograph 2800 of a stack of layers similar to that shown in FIG. 27B, which has undergone an etching process using the techniques described herein. As shown, no damage to the spacers, or to the doped semiconductor material 1708, has occurred. Additionally, although the etched region of the substrate may have a varying width (e.g., from left to right in the photograph 2800), the distance between the substrate 202 and the spacers 1602 on the sides of the etched region can have dimensions that fall within a predetermined tolerance range. For example, when implementing the present techniques, the width (sometimes referred to herein as the “critical dimension,” or “CD”) of the etched region between the substrate walls 2802 when divided by the width of the etched region between the spacers 2804, can be less than about 1.5. In this example photograph, the ratio of the width between the substrate walls 2802 and the width between the spacers 2804 is about 1.1. When this ratio is outside of this thresholds (e.g., greater than about 1.5), it may be an indication that damage to the doped semiconductor material 1708 or the spacers 1602 has occurred. Generally, it is preferable that the width 2802 is about equal to the width 2804.

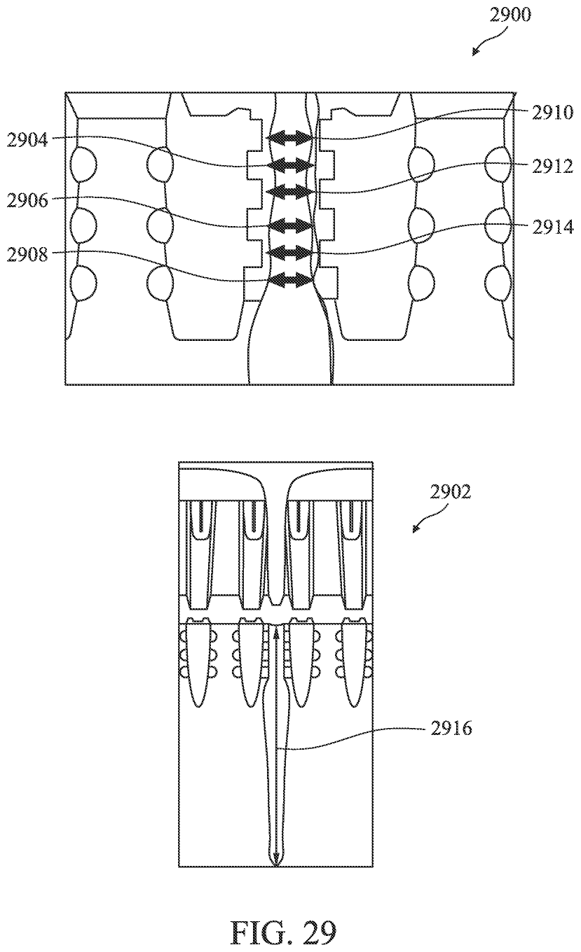

FIG. 29 shows a cross-sectional photographs 2900 and 2902 of a stack of layers similar to that shown in FIG. 28, which has undergone an etching process using the techniques described herein. As shown, no damage to the spacers, or to the doped semiconductor material 1708, has occurred. In this example, measurements were taken for each critical dimension between each layer of the substrate 202 and the spacers 1602, the measurement 2908 for top layer of the substrate has an average width of 16.7 nm, with a maximum width of 18.1 nm and a minimum width of 15.1 nm. The measurement 2904 between the top-most spacers 1602 has an average width of 14.5 nm, with a maximum width of 15.9 nm and a minimum width of 13.8 nm. The measurement 2912 between the second top-most layer of the substrate 202 has an average width of 15.9 nm, with a maximum width of 16.8 nm and a minimum width of 14.4 nm. The measurement 2906 between the middle-most spacers 1602 has an average width of 14.5 nm, with a maximum width of 15.3 nm and a minimum width of 13.2 nm. The measurement 2914 between the bottom-most substrate layer 202 has an average width of 17.0 nm, with a maximum width of 18.8 nm and a minimum width of 14.7 nm. The measurement 2908 between the bottom-most spacers 1602 has an average width of 15.6 nm, with a maximum width of 16.9 nm and a minimum width of 13.7 nm. The depth 2916 of the etched region has an average depth of 198.5 nm, a maximum depth of 217.2 nm, and a minimum depth of 177.6 nm.

FIG. 30 shows an example cross-sectional photograph of transistor devices made using the FEOL fabrication method of FIG. 1 with an overlay showing various etching stages used to carry out the CPODE techniques that do not result in transistor damage, in accordance with some embodiments. The etching process tools used to implement the present techniques can include an inductively coupled plasma (ICP) or dipole antenna plasma source driven by a radio-frequency (RF) power generator. Example frequencies of 13.56 MHz or 27 MHz may be utilized. The process chamber may be operated at a pressure in a range of about 3 mTorr to about 150 mTorr and a temperature of about 20 degrees Celsius to about 140 degrees Celsius. The RF power generator can be operated to provide source power between about 100 W to about 1500 W, and the output of the RF power generator can be controlled by a pulse signal having a duty cycle in a range of about 20% to 100%. An RF bias power can be provided to the pedestal, which can have a range of about 10 W to about 600 W.

To perform the etching process, particular etching conditions can be utilized to avoid damage to the various layers and to achieve the results described herein. As the vertical etch is performed from the top of the device towards the bottom, the etching process begins by etching through the hardmask 2006 and the PO material 1306. Prior to the boundary 3002, any suitable etching technique can be used to remove the PO material 1306. When the etching process reaches the boundary 3002, a low-selective etching process can be used to break through the fourth dielectric material layer 1204 (shown in FIG. 23). The gas used in the etching process can involve using 0 to 200 standard cubic centimeter per minute (sccm) of carbon tetrafluoride (CF₄), and 100 to 1000 sccm of argon (Ar) gas. Once the oxide layer has been etched, the direction etching process can continue in the region 3004. In this region, a highly selecting etching process of the substrate 202 to the spacers 1602 can be performed, in addition to SiO deposition process. The substrate etching process can utilize 100 to 1000 sccm of hydrogen bromide (HBr), 0 to 100 sccm of oxygen (O₂), and 100 to 1000 sccm of argon (Ar). The SiO deposition process can involve a deposition process and an oxidization process. The deposition process can be performed using 0 to 100 sccm of SiCl₄, 100 to 500 sccm of HBr, and 100 to 1000 sccm of Ar. The oxidization process can be performed with 10 to 200 sccm of O₂.

Once the second boundary 3006 has been reached after etching each of the substrate 202 layers and the layers of the sacrificial material 204 (not shown), another low-selective etching process can be performed. The low selective etching process can be used to break through a layer of SiO (or another dielectric layer, if present). The second low-selective etching process can involve using 0 to 200 sccm of CF₄, and 100 to 1000 sccm of Ar. After breaking through the layer of SiO (or another type of dielectric material), a further substrate etching process can be performed in the region 3008. The etching process can utilize 100 to 1000 sccm of hydrogen bromide (HBr), 0 to 100 sccm of oxygen (O₂), and 100 to 1000 sccm of argon (Ar). The substrate etching process can be performed through the substrate until an oxide layer on which the substrate layer is formed has been reached (e.g., in the case of a SOI device).

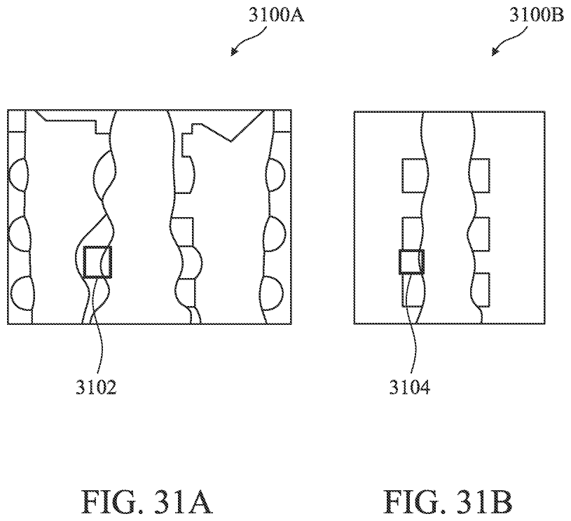

FIGS. 31A and 31B illustrate cross-sectional photographs 3100A and 3100B, respectively, comparing etching techniques that damage transistor devices and the present CPODE techniques, which do not damage transistor devices, in accordance with some embodiments. As shown in the photograph 3100A, an alternative etching process (e.g., other than that described in connection with FIG. 30) was performed, resulting in the damaged region 3102. In contrast, as shown in the photograph 3100B, which illustrates a similar device that has undergone etching using the techniques described herein, a corresponding region 3104 is undamaged by the etching process, resulting in an improved device.

Corresponding to operation 138 of FIG. 1, FIG. 25 shows a perspective view 2500 and cross-sectional views 2502 and 2504 of the stack of layers following the deposition of one or more dielectric materials in the etched region of the device. As shown, a first thin layer of a dielectric fill material 2506 is first deposited over the entire device. The dielectric fill material 2506 can be any suitable dielectric material, including silicon oxide, silicon oxynitride, or the like. After forming the layer of the dielectric fill material 2506, a second dielectric fill material 2508 can be formed. The second dielectric fill material 2508 can be formed of silicon nitride, silicon oxynitride, silicon carbonitride, or the like. The dielectric fill material 2506 and the second dielectric fill material 2508 can each be formed using a suitable material deposition technique, such as ALD, CVD, PVD, FCVD, or the like.

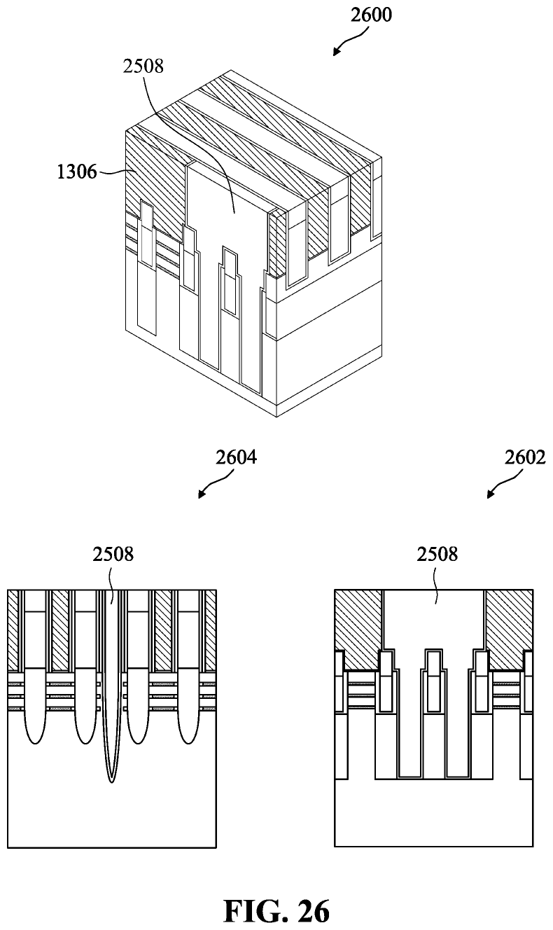

Still corresponding to operation 138 of FIG. 1, FIG. 26 shows a perspective view 2600 and cross-sectional views 2602 and 2604 of the stack of layers after a CMP process has been performed. After the second dielectric fill material 2508 has been deposited, a planarization process, such as a CMP process, may be performed to achieve a level upper surface for the device. The CMP may also remove the hardmask layer 2006 and the upper portions of the dielectric fill material 2506. After the planarization process, the upper surface of the second dielectric fill material 2508 is level with the upper surface of the PO material 1306, in some embodiments.

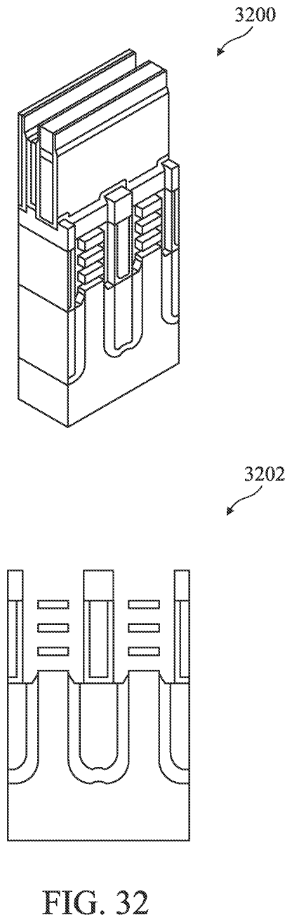

Corresponding to operation 140 of FIG. 1, FIG. 32 shows a perspective view 3200 and a cross-sectional view 3202 of the stack of layers following the removal of the PO material 1306, the fourth dielectric material 1204, and the sacrificial material 204. As shown in the cross-sectional view 3202, individual layers of the substrate 202 are exposed, which will be used to grow semiconductive material to form transistor devices in later process steps. This exposes the spacers 1602 between each of the substrate layers 202. The PO material 1306 can be removed, for example, using a selective etching process, which may include a wet etching process, a dry etching process, a plasma etching process, or the like.

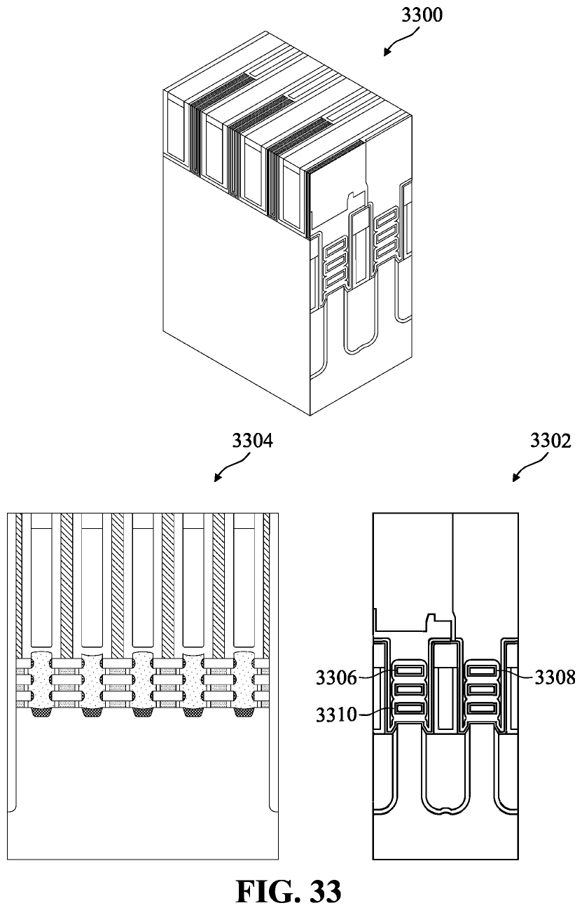

Corresponding to operation 138 of FIG. 1, FIG. 33 shows a perspective view 3300 and cross-sectional views 3302 and 3304 of the stack of layers. As shown, the PO material 1306, which previously acted as a dummy gate, has been replaced with active gate materials. Additionally, channel material 3306 has been grown on the layers of the substrate material 202 form channel regions. The channel material 3306 can include an epitaxial material suitable for an intended type (e.g., N-type or P-type) of semiconductor device to be formed. The channel materials 3306 may be doped to achieve a charge-carrier density using various impurities. P-type impurities, such as boron or indium, may be implanted in the channel materials 3306 of a P-type transistor. N-type impurities, such as phosphorous or arsenide, may be implanted in the channel materials 3306 of an N-type transistor. In some embodiments, the channel materials 3306 may be in situ doped during their growth.

The active gate regions can be formed on the channel regions to create transistor devices in the stack of layers. The active gate structures can include a gate dielectric layer 3308, a metal gate layer 3310, and one or more other layers that are not shown for clarity. For example, each of the active gate structures may further include a capping layer and a glue layer. The capping layer can protect the underlying work function layer from being oxidized. In some embodiments, the capping layer may be a silicon-containing layer, such as a layer of silicon, a layer of silicon oxide, or a layer of silicon nitride. The glue layer can function as an adhesion layer between the underlying layer and a subsequently formed gate electrode material (e.g., tungsten) over the glue layer. The glue layer may be formed of a suitable material, such as titanium nitride.

The gate dielectric layers 3308 can be each deposited to surround the semiconductive material that is grown on the layers of the substrate 202. The gate dielectric layers 3308 may include silicon oxide, silicon nitride, or multilayers thereof. In example embodiments, the gate dielectric layers 3308 each include a high-k dielectric material, and in these embodiments, the gate dielectric layers 3308 may each have a k value greater than about 7.0, and may include a metal oxide or a silicate of Hf, Al, Zr, La, Mg, Ba, Ti, Pb, or combinations thereof. The formation methods of the gate dielectric layers 3308 may include molecular beam deposition (MBD), ALD, and the like. A thickness of each of the gate dielectric layers may be between about 8 angstroms (Å) and about 20 Å, as an example.

The metal gate layers 3310 can each be formed over the respective gate dielectric layer. The metal gate layer 3310 can be formed vertically in the region previously occupied by the PO material 1306. The metal gate layers 3310 may each be a P-type work function layer, an N-type work function layer, multi-layers thereof, or combinations thereof, in some embodiments. Accordingly, the metal gate layers 3310 may each be referred to as a work function layer, in some embodiments. In the discussion herein, a work function layer may also be referred to as a work function metal. Example P-type work function metals that may be included in the gate structures for P-type devices include TiN, TaN, Ru, Mo, Al, WN, ZrSi₂, MoSi₂, TaSi₂, NiSi₂, WN, other suitable P-type work function materials, or combinations thereof. Example N-type work function metals that may be included in the gate structures for N-type devices include Ti, Ag, TaAl, TaAlC, TiAlN, TaC, TaCN, TaSiN, Mn, Zr, other suitable N-type work function materials, or combinations thereof.

After replacing the dummy gate structures with the active gate structures, a number of contacts can be formed to electrically connect the respective structures. For example, gate contacts and can be formed to electrically connect the active gate structures, and source/drain contacts can be formed to electrically connect the source/drain structures (e.g., the doped semiconductor material 1706 and 1708).

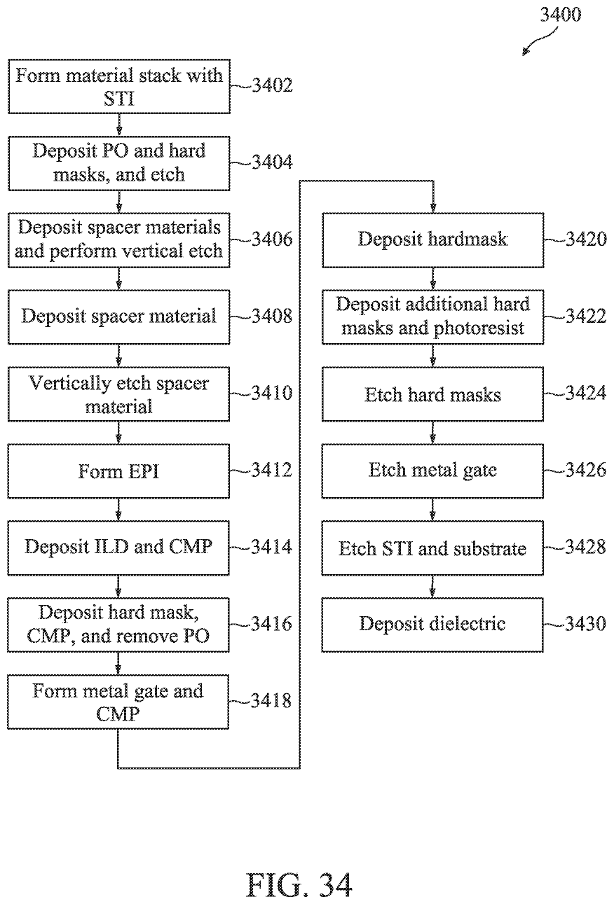

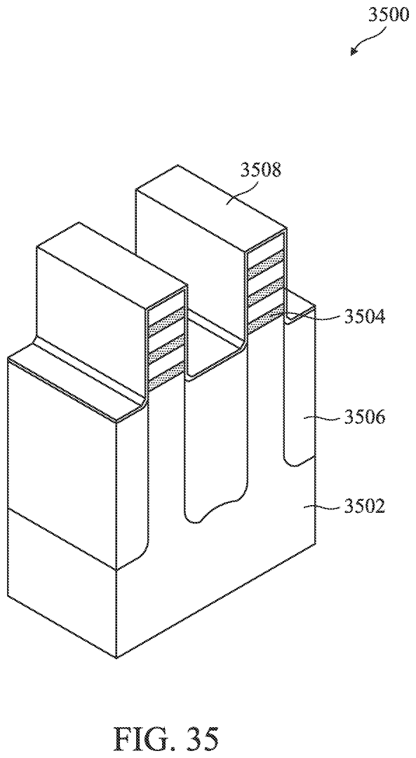

FIG. 34 illustrates a flowchart of an example method 3400 for making transistor devices using a middle end of line (MEOL) fabrication process in connection with the CPODE processes described herein, in accordance with some embodiments. For example, at least some of the operations (or steps) of the method 3400 can be used to form transistor devices, such as a nanosheet transistor devices, nanowire transistor devices, vertical transistor devices, or the like, and to electrically isolate the transistor devices from one another according to a predetermined design using CPODE techniques. It is noted that the method 3400 is merely an example, and is not intended to limit the present disclosure. Accordingly, it is understood that additional operations may be provided before, during, and after the method 3400 of FIG. 34, and that some other operations may only be briefly described herein. Additionally, operations of the method 3400 may be performed in an order different from that described herein to achieve desired results. In some embodiments, operations of the method 100 may be associated with the various perspective and cross-sectional views of the transistor devices at various fabrication stages as shown in FIGS. 35, 36, 37, 38, 39, 40, 41, 42, 43, 44, 45, 46, 47, 48, and 49 respectively, which will be discussed in further detail below.

In brief overview, the method 3400 starts with operation 3402 of forming layers on a substrate with shallow trench isolation (STI). The method 3400 continues to operation 3404 of depositing PO material and hardmasks, and performing an etching process. The method 3400 continues to operation 3406 of depositing spacer materials and performing a vertical etching process. The method 3400 continues to operation 3408 of depositing spacer material. The method 3400 continues to operation 3410 of vertically etching the spacer material. The method 3400 continues to operation 3412 of epitaxially forming semiconductive material. The method 3400 continues to operation 3414 of depositing an ILD material and performing a CMP process. The method 3400 continues to operation 3416 of depositing a hardmask, performing a CMP process, and removing the PO material. The method 3400 continues to operation 3418 of forming the metal gate materials and performing a CMP process. The method 3400 continues to operation 3420 of depositing a hardmask for a CPODE process. The method 3400 continues to operation 3422 of depositing additional hardmasks and photoresist. The method 3400 continues to operation 3424 of etching the hardmasks. The method 3400 continues to operation 3426 of etching the metal gate. The method 3400 continues to operation 3428 of etching the STI and substrate. The method 3400 continues to operation 3430 of depositing a dielectric.

As mentioned above, FIGS. 35-49 illustrate, in various cross-sectional and perspective views, a portion of three-dimensional transistor devices at various fabrication stages of the method 3400 of FIG. 34. It should be understood that the process steps shown in FIGS. 35-49 may include a number of other devices such as inductors, fuses, capacitors, coils, etc., which are not shown in FIGS. 35-49, for purposes of clarity of illustration.

Corresponding to operation 3402 of FIG. 34, FIG. 35 is a perspective view 3500 of a stack of layers that used to manufacture semiconductor devices using the techniques described herein. The stack of layers can be formed on a semiconductor substrate 3502, and can include a number of alternating layers of the substrate material 3502 and a sacrificial material 3504. The semiconductor material of the substrate 3502 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof. The one or more layers of the sacrificial material 3504 may be formed on the substrate material 3502 using a material deposition process or an epitaxial growth process. The sacrificial material 3504 can be removed in later process steps, and can be formed from a material that has different material properties than the substrate material 3502, to facilitate selective removal or deposition techniques described herein. The sacrificial material 3504 can be an allow semiconductor material, such as SiGe.

Using processes similar to those described in connection with FIGS. 2-5, vertical structures can be formed using etching processes, and a STI dielectric material 3506 be formed in trenches between the vertical structures. The STI dielectric material 3506 can be any type of insulating material, including various oxides, such as silicon oxide, a nitride, or other insulators, or combinations thereof. The STI dielectric material 3506 can be formed using any suitable material deposition technique, including ALD, HDP-CVD, FCVD, the like, or combinations thereof. A top dielectric material 3508 can be formed to surround the top of the device, as shown in the perspective view 3500. The top dielectric material 3508 surrounding the top of the device may be a different dielectric material from the STI dielectric material 3506, and may be any suitable insulating material, such as an oxide material. The top dielectric material 3508 can be similar to the fourth dielectric material 1204 described in connection with FIG. 12. The top dielectric material 3508 can be formed using any suitable material deposition technique, including ALD, HDP-CVD, FCVD, the like, or combinations thereof.

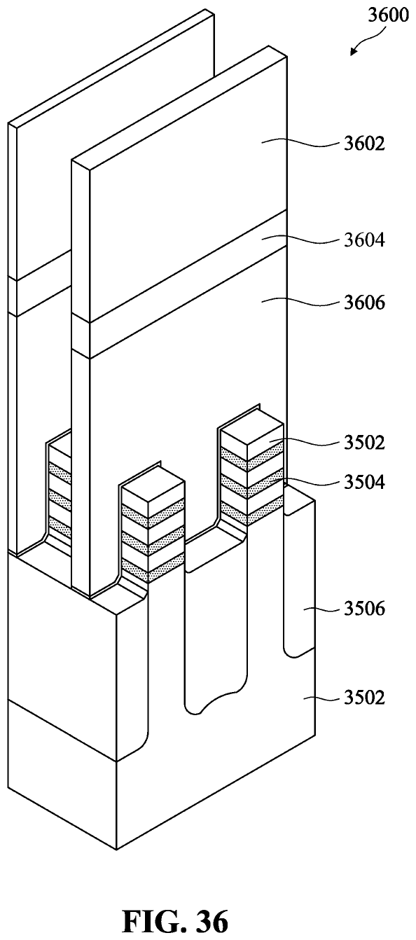

Corresponding to operation 3404 of FIG. 34, FIG. 36 is a perspective view 3600 of a stack of layers following the deposition and patterning of a PO material 3606. The PO material 3606 may be similar to the PO material 1306. To form the PO material 3606, deposited to cover the entirety of the device, over the layer of the top dielectric material 3508 described in connection with FIG. 35. The PO material 3606 can be, for example, a polysilicon material. The PO material 3606 can be used as a placeholder region, which will be removed in layer process steps to form metal gate materials. The PO material 3606 can be deposited using any suitable material deposition technique, including ALD, CVD, PVD, among other techniques. PO material 3606 can be deposited to a predetermined thickness, according to design parameters of the device.

After deposition, the PO material 3606 can be patterned and etched using the hardmasks 3602 and 3604. To pattern etch the PO material 3606, the hardmasks 3602 and 3604 can first be patterned on top of the PO material 3606, for example, using a photoresist material (not pictured), such that hardmasks 3602 and 3604 form strips that are perpendicular to the structures formed from the sacrificial material 3504 and the substrate material 3502, as shown. The hardmasks 3602 and 3604 can be similar to the third hardmask 1410 and the fourth hardmask 1408 described in connection with FIG. 14, and can be made from similar materials and formed using similar techniques. After depositing the hardmasks 3602 and 3604, the PO material 3606 can be selectively and vertically etched, such that the PO material 3606 below the hardmasks 3602 and 3604 is not removed by the etching process. Any suitable vertical etching process or material removal process can be used to remove the PO material 3606. Additionally, as shown, the top dielectric material 3508 that is not shielded from the etching process by the hardmasks 3602 and 3604 is removed, exposing the sacrificial material 3504 and the substrate material 3502.

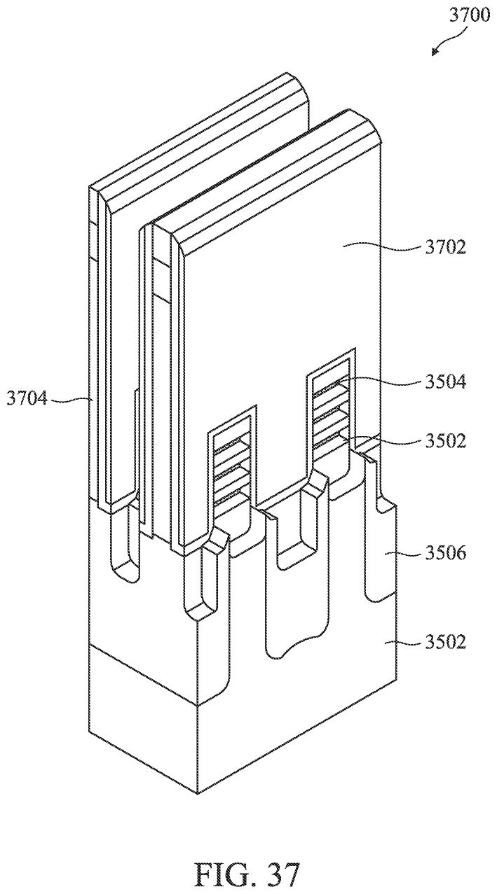

Corresponding to operation 3406 of FIG. 34, FIG. 37 is a perspective view 3700 of a stack of layers following the formation of liner and spacer materials. After etching the PO material 3606, a liner material 3704 can be deposited over the top of the device, covering the PO material 3606, the hardmasks 3602 and 3604, the substrate material 3502, and the sacrificial material 3504. The liner material 3704 can be similar to the liner material 708 described in connection with FIG. 7. The liner material 3704 can be any type of suitable insulating material, such as an oxide or another type of insulator. After depositing the liner material 3704, a layer of a spacer material 3702 is deposited over the device. When deposited, the layer of the spacer material 3702 evenly covers all materials on the surface of the device. The spacer material 3702 can be deposited using any suitable material deposition technique, such as ALD, CVD, PVD, among others. The spacer material can be used to protect materials on the device from etching processes in further process steps.

Then, vertical etching process can be performed to create a number of troughs in the substrate material 3502 and the STI dielectric material 3506. The vertical etching process can etch and recess the layers of the sacrificial material 3504, as shown. The hardmasks 3602 and 3604, and the spacer material 3702 protect the PO material 3606 from the etching process, such that it remains intact, along with the layer of the liner material 3704. Portions of the sacrificial material 3504 remain under each PO material 3606 structure. Any suitable etching process may be used to perform the vertical etch, including wet etching, dry etching, plasma etching, or the like. In some embodiments, a series of selective etching processes may be utilized to remove one or more types of material from the stack of layers.

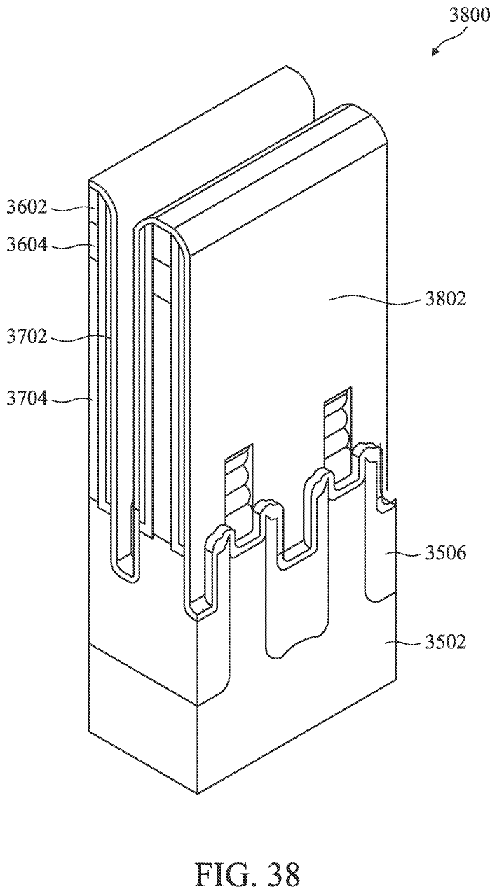

Corresponding to operation 3408 of FIG. 34, FIG. 38 is a perspective view 3800 of a stack of layers following the deposition of a layer of a spacer material 3802. The spacer material 3802 may be similar to the material making up the spacers 1602 described in connection with FIG. 16. For example, the spacer material 3802 can be formed from any type of suitable insulating material with a relatively low dielectric constant k, such as silicon oxide, silicon oxycarbonitride (SiOCN), or the like. Any suitable deposition method, such as thermal oxidation, CVD, or the like, may be used to form the layer of the spacer material 3802. As shown, the layer of the spacer material 3802 covers the entirety of the top of the device, and fills the air gaps left when recessing the sacrificial material 3504 as described in connection with FIG. 37. However, the shapes and formation methods of the spacer material 3802 as illustrated in FIG. 38 are merely non-limiting examples, and other shapes and formation methods are possible. These and other variations are fully intended to be included within the scope of the present disclosure.

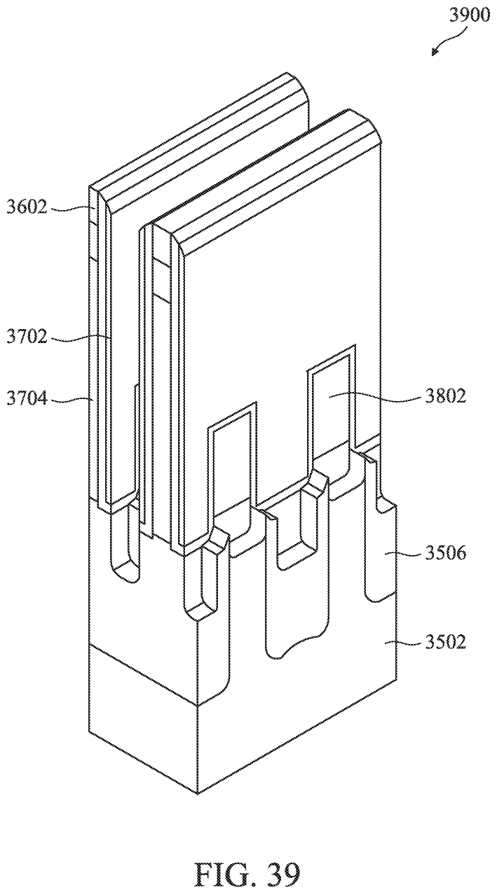

Corresponding to operation 3410 of FIG. 34, FIG. 39 is a perspective view 3900 of a stack of layers following an etching process that removes portions of the spacer material 3802. As shown, after the spacer material 3802 is deposited, a vertical etching process is performed to remove portions of the spacer material 3802 that surround the top of the device. Because the etching process is a vertical or directional etching process, the spacer material 3802 that was deposited in the recesses left when removing the sacrificial material 3504 were protected by the spacer material 3702 and the liner material 3704, and remain in the stack of layers. As shown, this also results in a portion of the spacer material 3802 covering the layers of the substrate material 3502. Any suitable etching process may be used to perform the directional etching process, including wet etching, dry etching, plasma etching, or the like. In some embodiments, the etching process may be an etching process that is selective to the spacer material 3802.

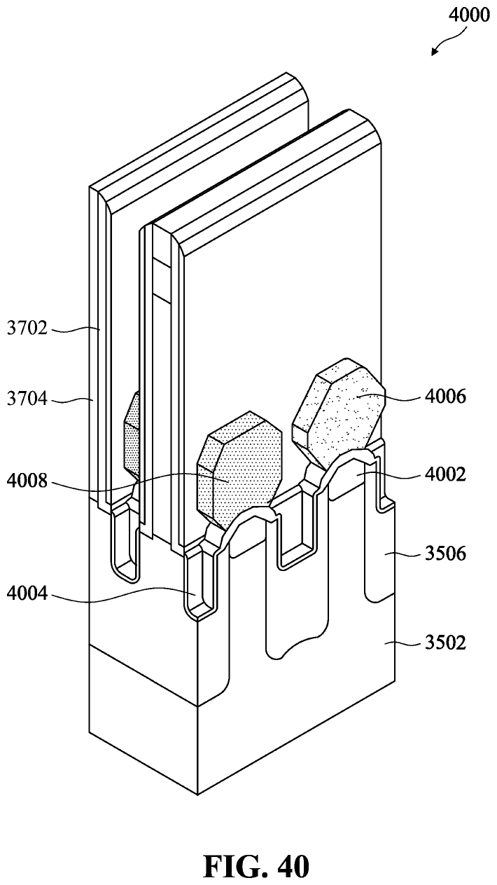

Corresponding to operation 3412 of FIG. 34, FIG. 40 is a perspective view 4000 of a stack of layers following the formation of the semiconductor materials 4006 and 4008. As shown, a filler material 4002 may first be formed in the troughs of the substrate material 3502 that are positioned beneath the spacer material 3802. The filler material 4002 may be deposited, for example, using processes ALD, CVD, PVD, or the like, in conjunction with a patterning or etching process, or may be epitaxially grown on the substrate material 3502, using the substrate material as a seed material. This enables the semiconductor materials 4006 and 4008 to be grown in alignment with the portions of the spacer material 3802. To isolate the semiconductor materials 4006 and 4008 from the filler material 4002, a layer of a dielectric material 4004 (or other insulation material) may be formed on the device. The dielectric material 4004 may be formed using a selective deposition or formation process, such that the dielectric material 4004 is formed on the STI dielectric material 3504 and the filler material 4002, as shown. The dielectric material 4004 may be formed of a suitable dielectric material, such as silicon oxide, silicon oxycarbonitride, or the like. In some embodiments, the dielectric material 4004 may be a high-k dielectric material, and may a high-k dielectric material, and may have a k value greater than about 7.0. In these embodiments, the dielectric material 4004 may include a metal oxide or a silicate of Hf, Al, Zr, La, Mg, Ba, Ti, Pb, or combinations thereof.

After forming the dielectric material 4004, the semiconductor materials 4006 and 4008 can be grown on the stack of layers. For example, the semiconductor materials 4006 and 4008 can be grown by utilizing the spacer material 3802 as a seed material for epitaxial growth. The semiconductor materials 4006 and 4008 can include an epitaxial material suitable for an intended type (e.g., N-type or P-type) of semiconductor devices to be formed. For example, the semiconductor material 4006 may be an N-type material, and the semiconductor material 4008 may be a P-type material. Various patterning techniques (e.g., by depositing and removing photoresist, etc.) may be utilized to pattern and grow the semiconductor materials 4006 and 4008 in desired regions of the stack of layers and at desired dimensions. As shown, the semiconductor materials 4006 and 4008 are grown between the vertical structures formed from the spacer material 3702.

The semiconductor materials 4006 and 4008 may be in situ doped during growth, which may obviate prior and subsequent implantations although in situ and implantation doping may be used together. Still further, it may be advantageous to epitaxially grow a material in an NMOS region different from the material in a PMOS region. In various embodiments, the semiconductor materials 4006 and 4008 may include any type of semiconductor, including doped silicon, silicon germanium (SiₓGe₁₋ₓ, where x can be between 0 and 1), silicon carbide, pure or pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like. The semiconductor materials 4006 and 4008 may be formed using suitable methods such as metal-organic CVD (MOCVD), molecular beam epitaxy (MBE), liquid phase epitaxy (LPE), vapor phase epitaxy (VPE), selective epitaxial growth (SEG), the like, or a combination thereof.

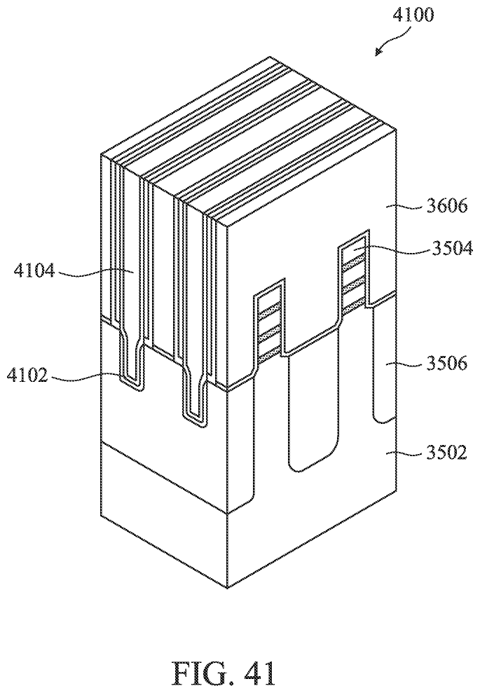

Corresponding to operation 3414 of FIG. 34, FIG. 41 is a perspective view 4000 of a stack of layers following the formation a CESL material 4102 and an ILD material 4104. First, a CESL material 4102 is formed over the semiconductor materials 4006 and 4008. The CESL material 4102 can function as an etch stop layer in a subsequent etching process, and may comprise a suitable material such as silicon oxide, silicon nitride, silicon oxynitride, combinations thereof, or the like, and may be formed by a suitable formation method such as CVD, PVD, combinations thereof, or the like.

Next, the ILD material 4104 is formed over the CESL material 4102. In some embodiments, the ILD material 1806 is formed of a dielectric material such as silicon oxide, PSG, BSG, BPSG, USG, or the like, and may be deposited by any suitable method, such as CVD, PECVD, or FCVD. After the ILD material 4104 is formed, an optional dielectric layer 1808 is formed over the ILD material 4104. As shown, the ILD material can fill the regions between the PO material 3606 structures, which act as dummy gates that will be replaced in later process steps. After forming the ILD material 4104, a CMP process may be performed to planarize the device, causing the ILD material 4104 to be level with the PO material 3606, in some embodiments. The CMP may also remove the hardmasks 3602 and 3604 and portions of the CESL material 4102.

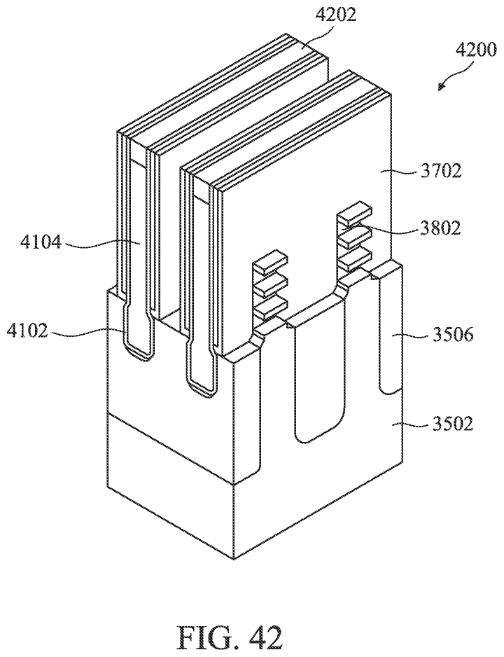

Corresponding to operation 3416 of FIG. 34, FIG. 42 is a perspective view 4200 of a stack of layers following the formation of a dielectric layer 4202 and the removal of the PO material 3606 and the sacrificial material 3504. After the ILD material 4104 is formed, a dielectric layer 4202 is formed over the ILD material 4104. The dielectric layer 4202 can function as a protection layer to prevent or reduces the loss of the ILD material 4104 in subsequent etching processes. The dielectric layer 4202 may be formed of a suitable material, such as silicon nitride, silicon carbonitride, or the like, using a suitable method such as CVD, PECVD, or FCVD. After the dielectric layer 4202 is formed, a planarization process, such as a CMP process, may be performed to achieve a level upper surface for the dielectric layer. After the planarization process, the upper surface of the dielectric layer 4202 may be level with the upper surface of the PO material 1306, in some embodiments.

After forming the dielectric layer 4202 and performing the CMP process, the PO material 3606 and the sacrificial material 3504 can be removed using one or more selective etching processes. As shown, individual layers of the substrate 3502 are exposed, which will be used to grow semiconductive material to form transistor devices in later process steps. The PO material 3606 can be removed, for example, using a selective etching process, which may include a wet etching process, a dry etching process, a plasma etching process, or the like. Additionally, the sacrificial material that was previously surrounded by the PO material 3606 and the substrate material 3502 can be removed. This exposes the spacer material 3802 between each of the substrate layers 3502, and provides space between each of the substrate layers 3502 for the growth of semiconductive channel materials and gate materials in further process steps.

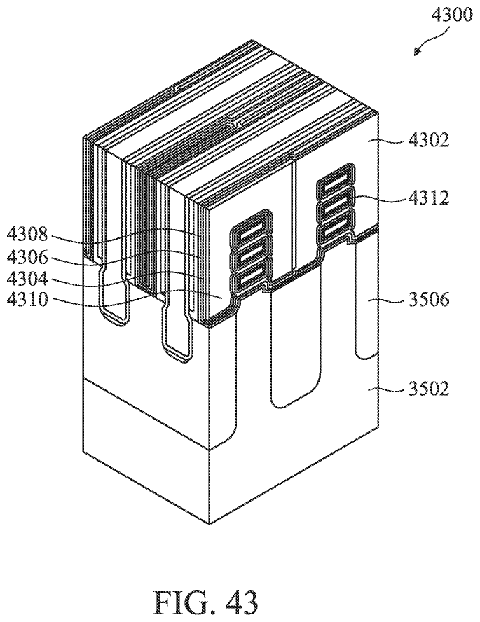

Corresponding to operation 3418 of FIG. 34, FIG. 43 is a perspective view 4300 of a stack of layers following the formation of channel and gate materials in place of the removed dummy gate. Prior to forming the gate materials on the substrate material 3502, a channel material 4312 has been grown using an epitaxial growth technique. The channel material 4312 can include an epitaxial material suitable for an intended type (e.g., N-type or P-type) of semiconductor device to be formed. The channel materials 4312 may be doped to achieve a charge-carrier density using various impurities. P-type impurities, such as boron or indium, may be implanted in the channel materials 4312 of a P-type transistor. N-type impurities, such as phosphorous or arsenide, may be implanted in the channel materials 4312 of an N-type transistor. In some embodiments, the channel materials 4312 may be in situ doped during their growth.

After forming the channel materials 4312, active gate regions can be formed on the channel materials 4312 to create transistor devices in the stack of layers. The active gate structures can include a gate dielectric layer 4308, a metal gate layer (e.g., one of the metal gate layers 4304 or 4306), and one or more other layers that are not shown for clarity. For example, each of the active gate structures may further include a capping layer and a glue layer. The capping layer can protect the underlying work function layer from being oxidized. In some embodiments, the capping layer may be a silicon-containing layer, such as a layer of silicon, a layer of silicon oxide, or a layer of silicon nitride. The glue layer can function as an adhesion layer between the underlying layer and a subsequently formed gate electrode material (e.g., tungsten) over the glue layer. The glue layer may be formed of a suitable material, such as titanium nitride.

The gate dielectric layers 4308 can be each deposited to surround the semiconductive material that is grown on the layers of the substrate 202. The gate dielectric layers 4308 may include silicon oxide, silicon nitride, or multilayers thereof. In example embodiments, the gate dielectric layers 4308 each include a high-k dielectric material, and in these embodiments, the gate dielectric layers 4308 may each have a k value greater than about 7.0, and may include a metal oxide or a silicate of Hf, Al, Zr, La, Mg, Ba, Ti, Pb, or combinations thereof. The formation methods of the gate dielectric layers 4308 may include molecular beam deposition (MBD), ALD, and the like. A thickness of each of the gate dielectric layers 4308 may be between about 8 angstroms (Å) and about 20 Å, as an example.

The metal gate layers 4304 and 4306 can each be formed over the respective gate dielectric layer 4308. The metal gate layers 4304 or 4306 can each be formed vertically in the region previously occupied by the PO material 1306, and may be isolated from one another by one or more dielectric layers (e.g., the dielectric layers 4302 and 4310). The metal gate layers may each be a P-type work function layer, an N-type work function layer, multi-layers thereof, or combinations thereof, in some embodiments. Accordingly, the metal gate layers may each be referred to as a work function layer, in some embodiments. In the discussion herein, a work function layer may also be referred to as a work function metal. Example P-type work function metals that may be included in the gate structures for P-type devices include TiN, TaN, Ru, Mo, Al, WN, ZrSi₂, MoSi₂, TaSi₂, NiSi₂, WN, other suitable P-type work function materials, or combinations thereof. Example N-type work function metals that may be included in the gate structures for N-type devices include Ti, Ag, TaAl, TaAlC, TiAlN, TaC, TaCN, TaSiN, Mn, Zr, other suitable N-type work function materials, or combinations thereof.

Each of the dielectric layers 4302 and 4310 may include any suitable dielectric material, such as silicon oxide, metal oxides, silicon nitride, or the like, and can be formed or otherwise selectively deposited using any suitable material deposition technique, including ALD, PVD, CVD, or the like. After replacing the dummy gate structures with the active gate structures, a number of contacts can be formed to electrically connect the respective structures. For example, gate contacts and can be formed to electrically connect the active gate structures, and source/drain contacts can be formed to electrically connect source/drain structures (e.g., the semiconductor material 4006 and 4008).

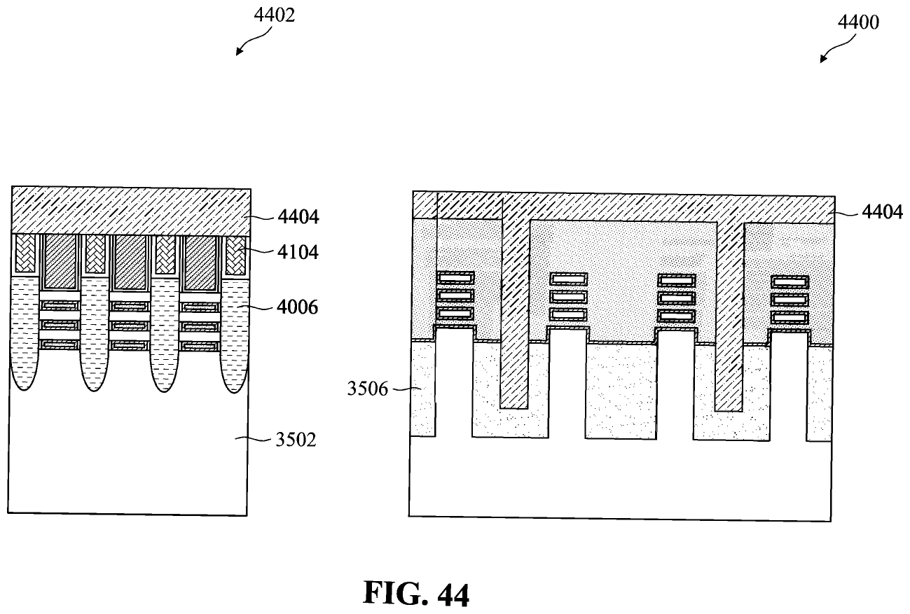

Corresponding to operation 3420 of FIG. 34, FIG. 44 shows cross-sectional views 4400 and 4402 of a stack of layers following the formation of the gate materials and at the start of a CPODE process used to isolate one or more transistor structures. At the start of the CPODE process, a hardmask layer 4404 can be deposited over the surface of the device. The hardmask layer 4404 can be any type of suitable dielectric material, including as silicon nitride, silicon carbonitride, or the like, and may be formed using a suitable method such as CVD, PECVD, or FCVD. After the hardmask layer 4404 is formed, a planarization process, such as a CMP process, may be performed. As shown, prior to depositing the hardmask layer 4404, two trenches can be etched the metal gate layers formed in the previous steps, thereby isolating the two middle stacks (as shown) of transistor devices from the other transistors in the device. The etching process can be any suitable etching process, and can be performed at a depth that penetrates a portion of the STI dielectric material 3504. After forming the trenches, the hardmask layer 4404 can be formed, which covers the top of the device and fills the etched trenches.

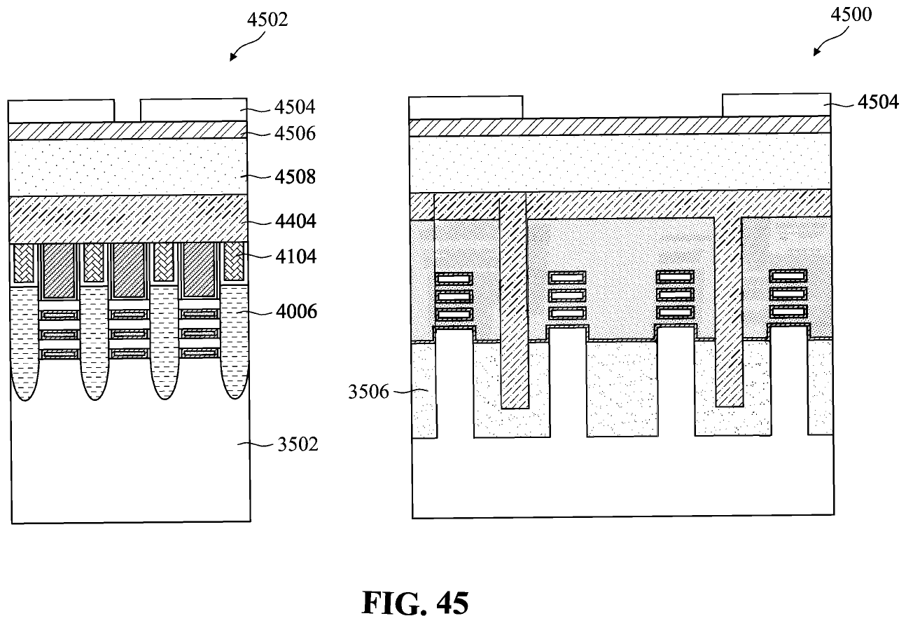

Corresponding to operation 3422 of FIG. 34, FIG. 45 shows cross-sectional views 4500 and 4502 of the stack of layers following the formation of the hardmask layer 4404. As shown, a second hardmask layer 4508 and a third hardmask layer 4506 are formed on top of the hardmask layer 4404, followed by a layer of patterned photoresist 4504. As shown, the patterned photoresist includes a slot-shaped opening, which is positioned to guide further etching processes. To pattern the photoresist 4504, the photoresist 4504 is deposited, irradiated (exposed), and developed to remove predetermined portions of the photoresist 4504. The remaining photoresist 4504 protects the underlying layers from subsequent processing steps, such as etching. The second hardmask layer 4508 and the third hardmask layer 4506 can include any suitable dielectric materials, including silicon oxide, silicon carbonitride, or the like, and can be deposited using any suitable material deposition technique, such as ALD, CVD, PVD, or the like.

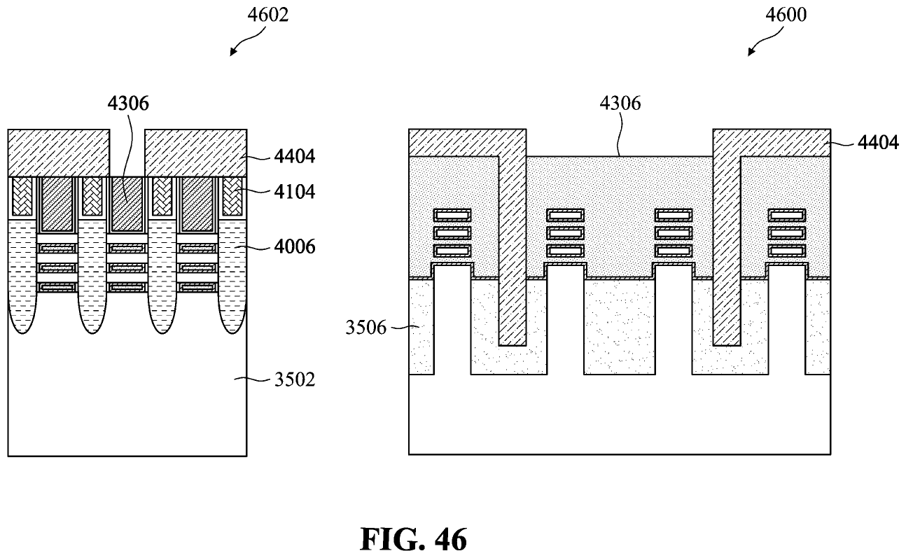

Corresponding to operation 3424 of FIG. 34, FIG. 46 shows cross-sectional views 4600 and 4602 of the stack of layers following an etching process applied to the hardmask layer 4404. Using one or more suitable etching processes, each of the photoresist 4504, the second hardmask layer 4508, and the third hardmask layer 4506 have been removed, along with a slot-shaped portion of the hardmask 4404. As shown, the slot-shaped portion that is removed from the hardmask 4404 was previously defined by the corresponding opening in the photoresist 4504. The etching process can be a vertical etching process towards the metal gate materials 4306, with the metal gate materials 4306 collectively serving as an etch stop layer. The etching processes may include wet etching processes, dry etching processes, plasma etching processes, or the like. One or more of the etching processes may be selective etching processes that are selective to one or more of the photoresist 4504, the second hardmask layer 4508, the third hardmask layer 4506, and the hardmask 4404.

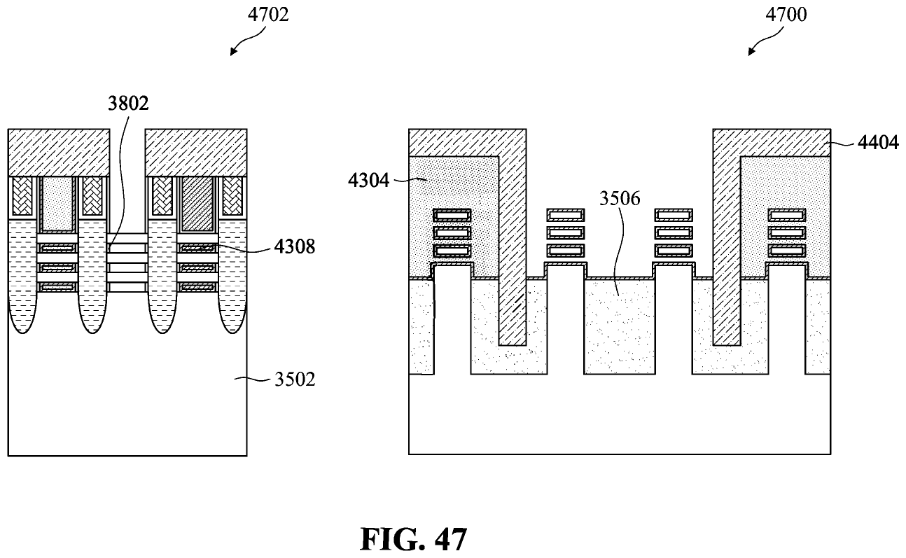

Corresponding to operation 3426 of FIG. 34, FIG. 47 shows cross-sectional views 4700 and 4702 of the stack of layers following an etching process that removes the metal gate materials 4306. As shown, the metal gate materials 4306 and the gate dielectric layers 4308 in the region between the vertical hardmask layer 4404 structures can be removed. In some embodiments, multiple etching processes that are selective to one or more of metal gate materials 4306 and the gate dielectric layers 4308, and de-selective to the substrate material 3502, may be used. Various etching approaches may be utilized, including wet etching processes, dry etching processes, plasma etching processes, or the like. As shown, after etching the material, the spacer material 3802 can be exposed in the stack of layers. The etching process may be performed with the substrate material 3502 or the STI dielectric material 3504 acting as an etch-stop.

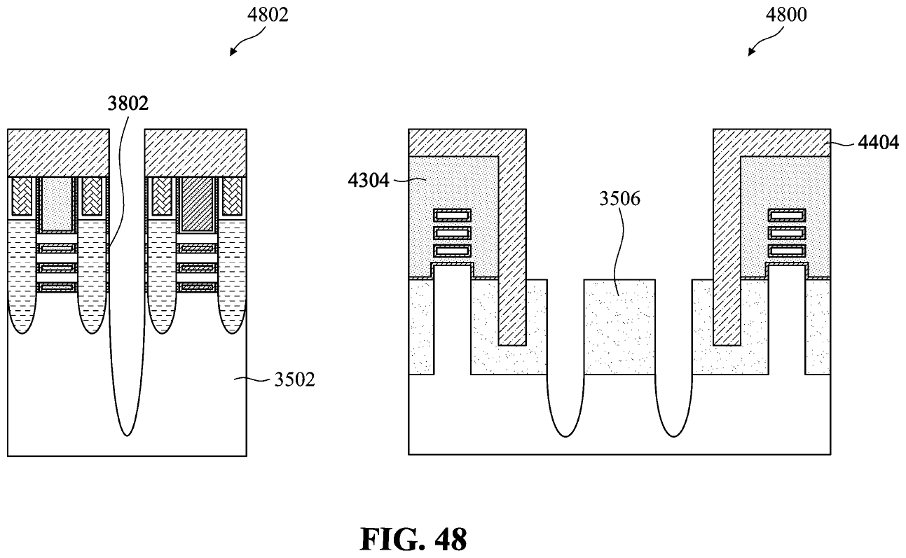

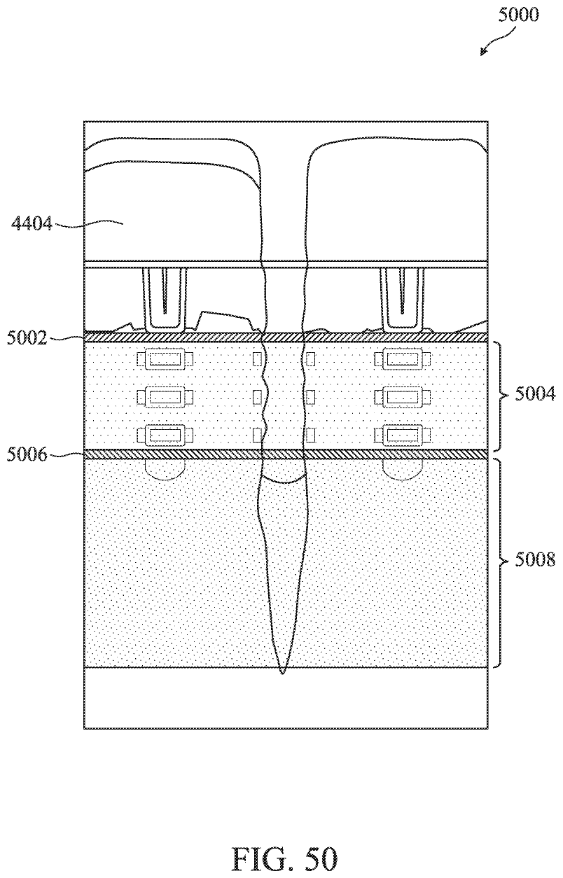

Corresponding to operation 3428 of FIG. 34, FIG. 48 shows cross-sectional views 4800 and 4802 of the stack of layers following a CPODE etching process that removes the substrate material between the layers of the spacer material 3802. At this stage in the CPODE process, one or more directional etching processes are utilized to remove portions the substrate material 3502, and some portions of the STI dielectric material 3504, that are positioned beneath the slot defined by the hardmask layer 4404. To do so, particular etching processes can be utilized to prevent damage to the spacers 3802 during material removal. Implementations that do not utilize the techniques described herein may cause damage to the structures in the stack of layers during the etching process. The etched openings shown in FIG. 48 are a result of utilizing the techniques described in connection with FIG. 50.

Referring to FIG. 50, shown is an example cross-sectional photograph 5000 of transistor devices made using the MEOL fabrication method of FIG. 34 with an overlay showing various etching stages used to carry out the CPODE techniques that do not result in transistor damage, in accordance with some embodiments. The etching process tools used to implement the present techniques can include an ICP or dipole antenna plasma source driven by a radio-frequency (RF) power generator. Example frequencies of 13.56 MHz or 27 MHz may be utilized. The process chamber may be operated at a pressure in a range of about 3 mTorr to about 150 mTorr and a temperature of about 20 degrees Celsius to about 140 degrees Celsius. The RF power generator can be operated to provide source power between about 100 W to about 1500 W, and the output of the RF power generator can be controlled by a pulse signal having a duty cycle in a range of about 20% to 100%. An RF bias power can be provided to the pedestal, which can have a range of about 10 W to about 600 W.

To perform the etching process, particular etching conditions can be utilized to avoid damage to the various layers and to achieve the results described herein. As the vertical etch is performed from the top of the device towards the bottom, the etching process begins by etching through the hardmask 4404. Prior to etching beyond the boundary 5002, an etching process utilizing 0 to 100 sccm of methane (CH₄) and 100 to 1000 sccm of argon (Ar) may be utilized. To etch the substrate material 3502 in the region 5004 a highly selecting etching process of the substrate 3502 to the spacers 3802 can be performed, in addition to SiO deposition process. The substrate etching process can utilize 100 to 1000 sccm of hydrogen bromide (HBr), 0 to 100 sccm of oxygen (O₂), and 100 to 1000 sccm of argon (Ar). This etching process can cut the nanosheets of the substrate material 3502. The SiO deposition process (which protects sidewall portions of the substrate material 3502) can involve a deposition process and an oxidization process. The deposition process can be performed using 0 to 100 sccm of SiCl₄, 100 to 500 sccm of HBr, and 100 to 1000 sccm of Ar. The oxidization process can be performed with 10 to 200 sccm of O₂.

Once the second boundary 5006 has been reached after etching each of the substrate material 3502 layers, a low-selective etching process can be performed. The low selective etching process can be used to break through a layer of SiO (or another dielectric layer, if present). The second low-selective etching process can involve using 0 to 200 sccm of CF₄, and 100 to 1000 sccm of argon (Ar). After breaking through the layer of SiO (or another type of dielectric material), a further substrate etching process can be performed in the region 3008. The etching process can utilize 100 to 1000 sccm of hydrogen bromide (HBr), 0 to 100 sccm of oxygen (O₂), and 100 to 1000 sccm of argon (Ar). The substrate etching process can be performed through the substrate until an oxide layer on which the substrate layer is formed has been reached (e.g., in the case of a SOI device).

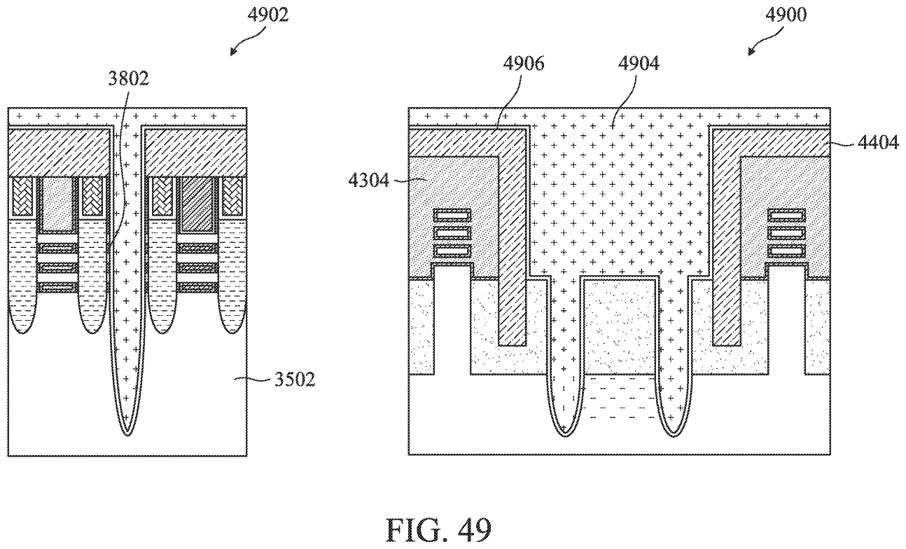

Corresponding to operation 3430 of FIG. 34, FIG. 49 shows cross-sectional views 4900 and 4902 of the stack of layers following the CPODE etching process. As shown, the region etched using the CPODE process can be filled with a liner material 4906 and a dielectric material 4904. First, a thin layer of the liner material 4906 is first deposited over the entire device. The liner material 4906 can be any suitable dielectric material, including silicon oxide, silicon oxynitride, or the like, and can be formed using techniques such as ALD, CVD, PVD, or the like. After forming the layer of the liner material 4906, the dielectric material 4904 can be formed. The dielectric material 4904 can be formed of silicon nitride, silicon oxynitride, silicon carbonitride, or the like. The dielectric material 4904 can each be formed using a suitable material deposition technique, such as ALD, CVD, PVD, FCVD, or the like. Although not shown here, after the dielectric material 4904 has been deposited, a planarization process, such as a CMP process, may be performed to achieve a level upper surface for the device. The CMP may also remove the hardmask layer 4404 and the upper portions of the liner material 4906.

In one aspect of the present disclosure, a semiconductor device is disclosed. The semiconductor device includes a first channel region extending in a first lateral direction, and comprising a first epitaxial structure and a second epitaxial structure. The semiconductor device includes a dielectric structure interposed between the first epitaxial structure and second epitaxial structure, and a plurality of first semiconductor sections interposed between a first sidewall of the dielectric structure and the first epitaxial structure. The semiconductor device includes a plurality of first dielectric sections interposed between the first sidewall of the dielectric structure and the first epitaxial structure, wherein the first dielectric sections are alternately arranged with the first semiconductor sections. The semiconductor device includes a plurality of second semiconductor sections interposed between a second sidewall of the dielectric structure and the second epitaxial structure, and a plurality of second dielectric sections interposed between the second sidewall of the dielectric structure and the second epitaxial structure, wherein the second dielectric sections are alternately arranged with the second semiconductor sections. A ratio of a first distance between laterally aligned ones of the first semiconductor sections and the second semiconductor sections, respectively, to a second distance between laterally aligned ones of the first dielectric sections and the second dielectric sections, respectively, is less than a threshold.

In another aspect of the present disclosure, a semiconductor device is disclosed. The semiconductor device includes a first channel region extending in a first lateral direction, and comprising a first epitaxial structure. The semiconductor device includes a dielectric structure extending in a second lateral direction and disposed next to the first epitaxial structure, and a plurality of first semiconductor sections interposed between a first sidewall of the dielectric structure and the first epitaxial structure. The semiconductor device includes a plurality of first dielectric sections interposed between the first sidewall of the dielectric structure and the first epitaxial structure, wherein the first dielectric sections are alternately arranged with the first semiconductor sections. The dielectric structure has a second sidewall opposite to the first sidewall in the first lateral direction, and wherein a maximum variance percentage of a distance between the first sidewall and second sidewall is less than about 50%.

In yet another aspect of the present disclosure, a method for fabricating semiconductor devices is disclosed. The method includes forming a plurality of channel regions over a substrate, wherein the plurality of channel regions, in parallel with one another, extend along a first lateral direction, and wherein each of the plurality of channel regions includes a plurality of semiconductor layers vertically spaced from one another and in contact with a pair of epitaxial structures. The method includes forming a gate structure over the plurality of channel structures, wherein the gate structure extends along a second lateral direction. The method includes removing, through a first etching process, a portion of the gate structure that was disposed over at least one of the plurality of channel regions. The method includes removing, through a second etching process, respective first portions of the corresponding semiconductor layers of the at least one channel region with at least respective second portions of the corresponding semiconductor layers extending along the pair of epitaxial structures. The method includes removing, through a third etching process, a portion of the substrate that was disposed below the removed semiconductor layers.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a first channel region extending in a first lateral direction, and comprising a first epitaxial structure and a second epitaxial structure;
a dielectric structure interposed between the first epitaxial structure and the second epitaxial structure;
a plurality of first semiconductor sections interposed between a first sidewall of the dielectric structure and the first epitaxial structure;
a plurality of first dielectric sections interposed between the first sidewall of the dielectric structure and the first epitaxial structure, wherein the first dielectric sections are alternately arranged with the first semiconductor sections;
a plurality of second semiconductor sections interposed between a second sidewall of the dielectric structure and the second epitaxial structure; and
a plurality of second dielectric sections interposed between the second sidewall of the dielectric structure and the second epitaxial structure, wherein the second dielectric sections are alternately arranged with the second semiconductor sections;
wherein a ratio of a first distance between laterally aligned ones of the first semiconductor sections and the second semiconductor sections, respectively, to a second distance between laterally aligned ones of the first dielectric sections and the second dielectric sections, respectively, is less than a threshold.

2. The semiconductor device of claim 1, wherein the threshold is about 1.5.

3. The semiconductor device of claim 1, wherein the dielectric structure extends in a second lateral direction perpendicular to the first lateral direction.

4. The semiconductor device of claim 1, further comprising a second channel region disposed in parallel with the first channel region, and comprising a third epitaxial structure and a fourth epitaxial structure.

5. The semiconductor device of claim 4, wherein the dielectric structure is also interposed between the third epitaxial structure and fourth epitaxial structure.

6. The semiconductor device of claim 1, further comprising a third channel region disposed in parallel with the first channel region, and comprising a fifth epitaxial structure and a sixth epitaxial structure.

7. The semiconductor device of claim 6, further comprising a first active gate structure extending in the second lateral direction and in contact with the dielectric structure, wherein the first active gate structures wraps around each of a plurality of first semiconductor layers.

8. The semiconductor device of claim 7, wherein the fifth epitaxial structure and sixth epitaxial structure, disposed on opposite sides of the first active gate structure in the first lateral direction, are in electrical contact with the plurality of first semiconductor layers.

9. The semiconductor device of claim 1, further comprising a second active gate structure disposed in parallel with the dielectric structure, wherein the second active gate structures wraps around each of a plurality of second semiconductor layers.

10. The semiconductor device of claim 9, wherein the first or second epitaxial structure is in electrical contact with the plurality of second semiconductor layers.

11. A semiconductor device, comprising:
a first channel region extending in a first lateral direction, and comprising a first epitaxial structure;
a dielectric structure extending in a second lateral direction and disposed next to the first epitaxial structure;
a plurality of first semiconductor sections interposed between a first sidewall of the dielectric structure and the first epitaxial structure; and
a plurality of first dielectric sections interposed between the first sidewall of the dielectric structure and the first epitaxial structure, wherein the first dielectric sections are alternately arranged with the first semiconductor sections;
wherein the dielectric structure has a second sidewall opposite to the first sidewall in the first lateral direction, and wherein a maximum variance percentage of a distance between the first sidewall and second sidewall is less than about 50%.

12. The semiconductor device of claim 11, wherein the first channel region further comprises a second epitaxial structure spaced apart from the first epitaxial structure with the dielectric structure.

13. The semiconductor device of claim 12, further comprising:
a plurality of second semiconductor sections interposed between the second sidewall of the dielectric structure and the second epitaxial structure; and
a plurality of second dielectric sections interposed between the second sidewall of the dielectric structure and the second epitaxial structure, wherein the second dielectric sections are alternately arranged with the second semiconductor sections.

14. The semiconductor device of claim 11, further comprising an active gate structure extending in the second lateral direction and in contact with the dielectric structure, wherein the active gate structures wraps around each of a plurality of semiconductor layers formed in a second channel region in parallel with the first channel region.

15. The semiconductor device of claim 14, wherein the second channel region comprises a third epitaxial structure and a fourth epitaxial structure in electrical contact with the plurality of semiconductor layers.

16. The semiconductor device of claim 11, wherein the dielectric structure includes at least one of an oxide material or silicon nitride.

17. The semiconductor device of claim 11, wherein the dielectric structure downwardly extends beyond a bottom surface of the first epitaxial structure.

18. A method for fabricating semiconductor devices, comprising:
forming a plurality of channel regions over a substrate, wherein the plurality of channel regions, in parallel with one another, extend along a first lateral direction, and wherein each of the plurality of channel regions includes a plurality of semiconductor layers vertically spaced from one another and in contact with a pair of epitaxial structures;
forming a gate structure over the plurality of channel regions, wherein the gate structure extends along a second lateral direction;
removing, through a first etching process, a portion of the gate structure that was disposed over at least one of the plurality of channel regions;
removing, through a second etching process, respective first portions of the corresponding semiconductor layers of the at least one channel region with at least respective second portions of the corresponding semiconductor layers extending along the pair of epitaxial structures; and
removing, through a third etching process, a portion of the substrate that was disposed below the removed semiconductor layers.

19. The method of claim 18, wherein the second etching process further includes a silicon deposition process.

20. The method of claim 18, further comprising filling, with a dielectric material, an opening formed by the first to third etching processes, thereby electrically isolating the pair of epitaxial structures from each other.
